(19) United States
(12) Patent Application Publication
(10) Pub. No.: US 2026/0007049 A1
(43) Pub. Date: Jan. 1, 2026

(54) DISPLAY DEVICE HAVING A REFLECTIVE WALL

(71) Applicant: SAMSUNG DISPLAY CO., LTD., YONGIN-SI (KR)

(72) Inventors: Gi Hoon YANG, Yongin-si (KR); Ho LIM, Yongin-si (KR)

(21) Appl. No.: 19/010,461

(22) Filed: Jan. 6, 2025

(30) Foreign Application Priority Data
Jun. 26, 2024 (KR) 10-2024-0083781

(51) Int. Cl. H10K 59/80; H10K 59/38

(52) U.S. Cl. CPC H10K 59/878; H10K 59/38; H10K 59/871; H10K 59/879; H10K 59/8792

(57) ABSTRACT

A display device includes a first support substrate including light emitting areas and a non-light emitting area; an element layer including light emitting elements disposed in the light emitting areas; a sealing layer disposed on the element layer; and a color conversion layer disposed on the sealing layer. The color conversion layer includes a partition wall disposed in the non-light emitting area; and a reflective wall covering a side surface of the partition wall. The reflective wall includes a first reflective wall portion. The first reflective wall portion includes first inorganic layers having a first refractive index and second inorganic layers having a second refractive index and disposed alternately with the first inorganic layers, wherein the first refractive index and the second refractive index are different.

### CROSS-REFERENCE TO RELATED APPLICATION

This application claims priority under 35 U.S.C. 119 from Korean Patent Application No. 10-2024-0083781, filed on Jun. 26, 2024, in the Korean Intellectual Property Office, the disclosure of which in its entirety is herein incorporated by reference.

### BACKGROUND

### 1. Technical Field

The present disclosure relates to a display device, and more particularly to a display device having a reflective wall.

### 2. Discussion of Related Art

As information-oriented societies evolve, various demands are emerging for display devices. For example, display devices are being employed by a variety of electronic devices such as smartphones, digital cameras, laptop computers, navigation devices, and smart televisions, which may each have their own implementation specific demands.

The display devices may be flat panel display devices such as liquid crystal display devices, field emission display devices, or light emitting display devices. The light emitting display devices may include organic light emitting display devices including organic light emitting elements, inorganic light emitting display devices including inorganic light emitting elements such as inorganic semiconductors, and micro or nano light emitting display devices including micro or nano light emitting elements.

The organic light emitting display devices may display images using light emitting elements each including a light emitting layer made of an organic light emitting material. The organic light emitting display devices including self-light emitting elements may have improved performance in terms of power consumption, response speed, emission efficiency, luminance, and wide viewing angle compared to other display devices.

### SUMMARY

The display device may include a color conversion layer that converts or transmits light emitted from at least one of the light emitting elements into light of a different wavelength band.

The color conversion layer may be disposed on a sealing layer covering the light emitting elements.

Accordingly, when a process of disposing the color conversion layer includes a process in a high-temperature environment, the light emitting elements and the sealing layer may be damaged by the high temperature environment.

Aspects of the present disclosure provide a display device that includes a color conversion layer while inhibiting or preventing damage to light emitting elements and a sealing layer due to a process of disposing the color conversion layer.

However, aspects of the present disclosure are not restricted to those set forth herein. The above and other aspects of the present disclosure will become more apparent to one of ordinary skill in the art to which the present disclosure pertains by referencing the detailed description of the present disclosure given below.

According to an aspect of the present disclosure, there is provided a display device comprising a first support substrate including light emitting areas arranged in parallel and a non-light emitting area between the light emitting areas; an element layer disposed on the first support substrate and including light emitting elements disposed in the light emitting areas; a sealing layer disposed on the element layer; and a color conversion layer disposed on the sealing layer. The color conversion layer includes a partition wall disposed in the non-light emitting area; and a reflective wall covering a side surface of the partition wall. The reflective wall includes a first reflective wall portion. The first reflective wall portion includes first inorganic layers having a first refractive index and second inorganic layers having a second refractive index and disposed alternately with the first inorganic layers, wherein the first refractive index and the second refractive index are different.

Each of the first inorganic layers is disposed with a first thickness and each of the second inorganic layers is disposed with the first thickness.

The first substrate further includes a color conversion capping layer covering the color conversion layer. The color conversion capping layer includes a first color conversion capping portion disposed in at least one of the light emitting areas and the non-light emitting area. The first color conversion capping portion includes third inorganic layers having a third refractive index and fourth inorganic layers having a fourth refractive index and disposed alternately with the third inorganic layers, wherein the third refractive index and the fourth refractive index are different. Each of the third and fourth inorganic layers is disposed with a second thickness less than the first thickness.

The light emitting areas include a first light emitting area emitting light in a first wavelength band; a second light emitting area emitting light in a second wavelength band lower than the first wavelength band; and a third light emitting area emitting light in a third wavelength band lower than the second wavelength band. The light emitting elements emit light in a fourth wavelength band which is equal to or lower than the third wavelength band. The color conversion layer further includes a first color conversion portion disposed in the first light emitting area and converting the light in the fourth wavelength band into the light in the first wavelength band; a second color conversion portion disposed in the second light emitting area and converting the light in the fourth wavelength band into the light in the second wavelength band; and a light transmitting portion disposed in the third light emitting area and transmitting and scattering the light in the fourth wavelength band. The partition wall is disposed between the first color conversion portion, the second color conversion portion, and the light transmitting portion. The first reflective wall portion is disposed between each of the first color conversion portion and the second color conversion portion and the partition wall.

The first thickness is about 95 nm to about 105 nm.

The first reflective wall portion is further disposed between the light transmitting portion and the partition wall.

The reflective wall further includes a second reflective wall portion disposed between the light transmitting portion and the partition wall. The second reflective wall portion includes fifth inorganic layers having a fifth refractive index and sixth inorganic layers having a sixth refractive index and disposed alternately with the fifth inorganic layers, wherein the fifth refractive index and the sixth refractive index are different. Each of the fifth and sixth inorganic layers is disposed with a third thickness less than the first thickness.

The third thickness is about 65 nm to about 75 nm.

The first color conversion capping portion is disposed in the first light emitting area and the non-light emitting area. The second thickness is about 65 nm to about 75 nm.

The first color conversion capping portion is further disposed in the second light emitting area and the third light emitting area.

The color conversion capping layer further includes a second color conversion capping portion disposed in the third light emitting area. The first color conversion capping portion is further disposed in the second light emitting area. The second color conversion capping portion includes seventh inorganic layers having a seventh refractive index and eighth inorganic layers having an eighth refractive index and disposed alternately with the seventh inorganic layers, wherein the seventh refractive index and the eighth refractive index are different. Each of the seventh and eighth inorganic layers is disposed with a fourth thickness less than the second thickness.

The fourth thickness is about 15 nm to about 25 nm.

The first color conversion capping portion covers an edge portion of the second color conversion capping portion.

The color conversion capping layer further includes a second color conversion capping portion disposed in the third light emitting area; and a third color conversion capping portion disposed in the second light emitting area. The second color conversion capping portion includes seventh inorganic layers having a seventh refractive index and eighth inorganic layers having an eighth refractive index and disposed alternately with the seventh inorganic layers, wherein the seventh refractive index and the eighth refractive index are different. The third color conversion capping portion includes ninth inorganic layers having a ninth refractive index and tenth inorganic layers having a tenth refractive index and disposed alternately with the ninth inorganic layers, wherein the ninth refractive index and the tenth refractive index are different. Each of the seventh and eighth inorganic layers is disposed with a fourth thickness less than the second thickness. Each of the ninth and tenth inorganic layers is disposed with a fifth thickness greater than the first thickness.

The fourth thickness is about 15 nm to about 25 nm. The fifth thickness is about 195 nm to about 205 nm.

The first color conversion capping portion covers an edge portion of each of the second color conversion capping portion and the third color conversion capping portion.

The display device further comprises a first substrate and a second substrate facing the first substrate, wherein the first substrate includes the first support substrate, the element layer, the sealing layer, and the color conversion layer, and wherein the second substrate includes a second support substrate facing the first substrate and including the light emitting areas and the non-light emitting area; a color filter layer disposed on a surface of the second support substrate; and a filter capping layer covering the color filter layer. The color filter layer includes a first filter portion disposed in the first light emitting area and transmitting the light in the first wavelength band; a second filter portion disposed in the second light emitting area and transmitting the light in the second wavelength band; a third filter portion disposed in the third light emitting area and transmitting the light in the third wavelength band; and a light blocking portion defining the non-light emitting area.

The display device further comprises a filling layer filling a space between the first substrate and the second substrate. The filling layer is disposed between the color conversion capping layer and the filter capping layer.

An inorganic layer of the first inorganic layers is in contact with the color conversion layer. The first refractive index of about 1.7 to about 2.0. The second refractive index of about 1.48 to about 1.6.

An inorganic layer of the third inorganic layers is in contact with the color conversion layer. The third refractive index of about 1.48 to about 1.6. The fourth refractive index of about 1.7 to about 2.0.

According to an aspect of the present disclosure, there is provided a display device comprising a first support substrate including light emitting areas arranged in parallel and a non-light emitting area between the light emitting areas, an element layer disposed on the first support substrate and including light emitting elements disposed in the light emitting areas, a sealing layer disposed on the element layer, a color conversion layer disposed on the sealing layer, and a color conversion capping layer covering the color conversion layer and including a first color conversion capping portion disposed in at least one of the light emitting areas and the non-light emitting area. The color conversion layer includes a partition wall disposed in the non-light emitting area, and a reflective wall covering a side surface of the partition wall, the reflective wall includes a first reflective wall portion. The first reflective wall portion includes first inorganic layers having a first refractive index and second inorganic layers having a second refractive index and alternately disposed with the first inorganic layers, wherein the first refractive index and the second refractive index are different. The first color conversion capping portion includes third inorganic layers having a third refractive index and fourth inorganic layers having a fourth refractive index and alternately disposed with the third inorganic layers, wherein the third refractive index and the fourth refractive index are different.

According to an aspect of the present disclosure, there is provided an electronic device including a display device comprising a first substrate, and a second substrate facing the first substrate, wherein the first substrate includes a first support substrate including light emitting areas arranged in parallel and a non-light emitting area between the light emitting areas, an element layer disposed on the first support substrate and including light emitting elements disposed in the light emitting areas, a sealing layer disposed on the element layer, and a color conversion layer disposed on the sealing layer. The color conversion layer includes a partition wall disposed in the non-light emitting area, and a reflective wall covering a side surface of the partition wall. The reflective wall includes a first reflective wall portion. The first reflective wall portion includes first inorganic layers having a first refractive index and second inorganic layers having a second refractive index and alternately disposed with the first inorganic layers, wherein the first refractive index and the second refractive index are different.

The display device according to embodiments includes a first substrate and a second substrate which face each other. The first substrate includes a first support substrate including a display area including light emitting areas and non-light emitting areas, an element layer disposed on a first support substrate and including light emitting elements disposed in the light emitting areas, a sealing layer disposed on the element layer, and a color conversion layer disposed on the sealing layer and converting a wavelength band of light emitted from some of the light emitting elements. The color conversion layer includes a partition wall disposed in a non-light emitting area, and a reflective wall covering a side surface of the partition wall.

The reflective wall may include a first reflective wall portion disposed in at least a portion of the non-light emitting area.

The first reflective wall portion may include first inorganic layers and second inorganic layers including a material different from the first inorganic layers and disposed alternately with the first inorganic layers.

That is, at interfaces between the first inorganic layers and the second inorganic layers in the first reflective wall portion, light of a certain wavelength band may be reflected due to a difference in refractive indexes between the first inorganic layers and the second inorganic layers. That is, the first reflective wall portion may reflect light without including a reflective metal material deposited in a high-temperature environment.

A process of disposing the color conversion layer may omit a high-temperature environment, and damage to the light emitting elements and the sealing layers caused by the process of disposing the color conversion layer may be inhibited or prevented.

However, aspects and effects of embodiments are not restricted to those set forth herein. The above and other aspects and effects of embodiments will become more apparent to one of daily skill in the art to which embodiments pertain by referencing the claims.

### BRIEF DESCRIPTION OF THE DRAWINGS

The above and other aspects and features of the present disclosure will become more apparent by describing in detail embodiments thereof with reference to the attached drawings, in which:

FIG. 1 is a plan view illustrating a display device according to embodiments;

FIG. 2 is a cross-sectional view taken along line A-A′ of FIG. 1;

FIG. 3 is a plan view illustrating a display area and a circuit layer of portion B illustrated in FIG. 1;

FIG. 4 is a block diagram illustrating the circuit layer of portion B illustrated in FIG. 1;

FIG. 5 is an equivalent circuit diagram illustrating a light emitting pixel driver of FIG. 4;

FIG. 6 is a cross-sectional view taken along line C-C′ of FIG. 3 according to embodiments;

FIG. 7 is an enlarged view illustrating portion D of FIG. 6 according to an embodiment;

FIG. 8 is an enlarged view illustrating portion E of FIG. 6 according to an embodiment;

FIG. 9 is a cross-sectional view taken along line C-C′ of FIG. 3 according to an embodiment;

FIG. 10 is an enlarged view illustrating portion F of FIG. 9;

FIG. 11 is a cross-sectional view taken along line C-C′ of FIG. 3 according to an embodiment;

FIG. 12 is an enlarged view illustrating portion G of FIG. 11;

FIG. 13 is a cross-sectional view taken along line C-C′ of FIG. 3 according to an embodiment;

FIG. 14 is a cross-sectional view taken along line C-C′ of FIG. 3 according to an embodiment;

FIG. 15 is an enlarged view illustrating portion H of FIG. 14;

FIG. 16 is a cross-sectional view taken along line C-C′ of FIG. 3 according to an embodiment;

FIG. 17 is a simulation result graph illustrating reflectivity of each of a first reflective wall portion, a first color conversion capping portion, a second color conversion capping portion, and a third color conversion capping portion of FIG. 16;

FIGS. 18, 19, 20, 21, 22, 23, 24, 25, and 26 are process views illustrating a process of disposing a color conversion layer and a process of disposing a color conversion capping layer according to an embodiment of FIG. 16;

FIG. 27 is a block diagram illustrating an electronic device according to an embodiment of the present disclosure; and

FIG. 28 is a view illustrating an example in which the electronic device of FIG. 27 is implemented as a smart phone.

### DETAILED DESCRIPTION

The present disclosure will now be described more fully hereinafter with reference to the accompanying drawings, in which embodiments of the disclosure are shown. Aspects of this disclosure may, however, be provided in different forms and should not be construed as limiting embodiments set forth herein. Rather, embodiments are provided so that this disclosure will be thorough and complete, and will filly convey the scope of the disclosure to those skilled in the art.

In the accompanying figures, the thickness of layers and regions may be exaggerated for clarity. The same reference numbers indicate the same components throughout the disclosure and the accompanying figures.

Parts which are not associated with aspects of the description may not be described in order to more clearly describe embodiments of the disclosure.

It will also be understood that when a layer is referred to as being “on” another layer or substrate, the layer can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description and to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish elements or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within +30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

Hereinafter, embodiments will be described with reference to the accompanying drawings.

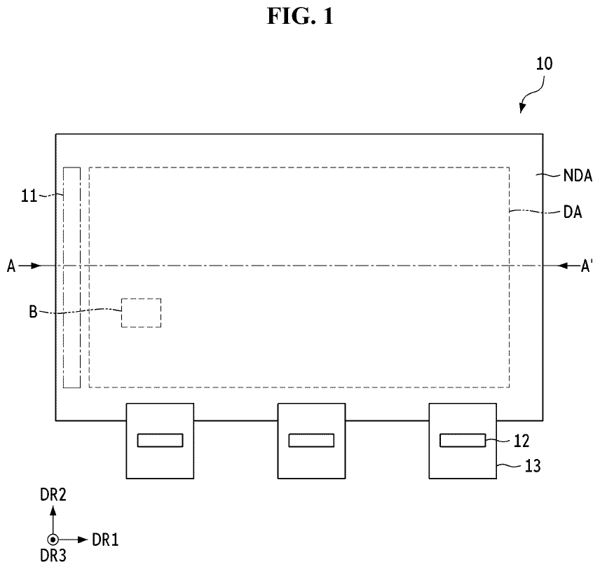

FIG. 1 is a plan view illustrating a display device according to some embodiments.

Referring to FIG. 1, a display device 10 according to embodiments may display a moving image or a still image, and may be used as a display screen of various products such as a television, a laptop computer, a monitor, a billboard, or an Internet of Things (IoT) device, as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, or an ultra-mobile PC (UMPC).

The display device 10 may be a light emitting display device such as an organic light emitting display device using an organic light emitting diode, a quantum dot light emitting display device including a quantum dot light emitting layer, an inorganic light emitting display device including an inorganic semiconductor, or a micro light emitting display device using a micro or nano light emitting diode (micro or nano LED). Hereinafter, aspects of the present disclosure will be described in the context of the display device 10 as an organic light emitting display device. However, the present disclosure is not limited thereto and may be aspects may be applied to display devices including organic insulating materials, organic light emitting materials, or metal materials.

The display device 10 may be formed to be flat, but is not limited thereto. For example, the display device 10 may include curved surface portions having a constant curvature or a variable curvature. In addition, the display device 10 may be flexibly formed to be curved, bent, folded, or rolled.

According to an embodiment, the display device 10 may be an organic light emitting display device.

As illustrated in FIG. 1, the display device 10 according to some embodiments may include a surface having a rectangular shape. However, this is only an example, and the shape of the display device 10 is not limited to that illustrated in FIG. 1. That is, the display device 10 according to some embodiments may include a surface having a shape of a rectangle, polygon, or circle. A portion of the display device 10 may be deformed from a flat, unfolded form to a bent, curved, folded, or rolled form.

A surface of the display device 10 may include a display area DA from which light for displaying an image may be emitted, and a non-display area NDA surrounding at least a portion of the display area DA.

The display area DA may be disposed over a surface of the display device 10.

The non-display area NDA may be in the form of a frame from which no light for displaying an image may be emitted. As an example, the non-display area NDA may be dyed or painted a specific color, such as black.

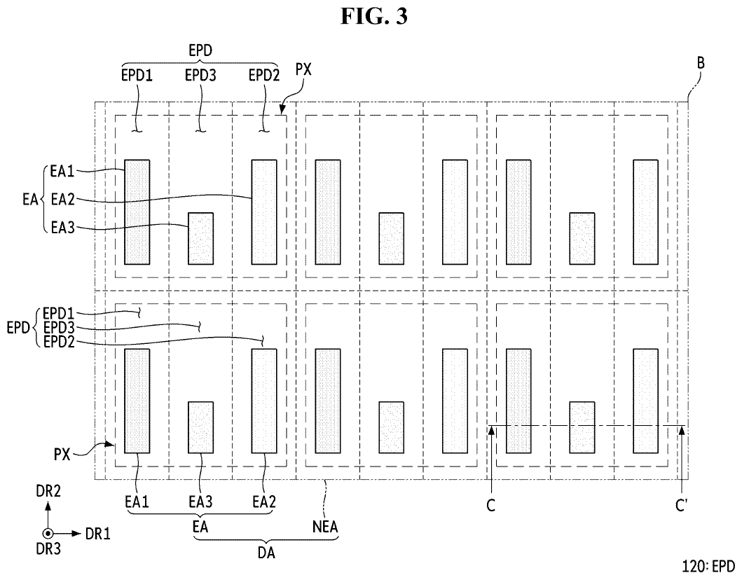

The display device 10 may include a first driver 11 and a second driver 12 that may transmit signals, voltages, or power to light emitting pixel drivers (EPD in FIGS. 3, 4, and 5) disposed in the display area DA.

One or more of the first driver 11 or the second driver 12 may be implemented with circuits disposed in the non-display area NDA.

One or more of the first driver 11 or the second driver 12 may be provided as integrated circuit chips. For example, the second driver 12 may be mounted on a circuit board 13 electrically connected to pads in the non-display area NDA. Alternatively, the second driver 12 may be mounted on the pads in the non-display area NDA.

One or more of the first driver 11 or the second driver 12 may be implemented in a plurality. For example, a plurality of second drivers 12 may be mounted on a plurality of circuit boards 13, respectively.

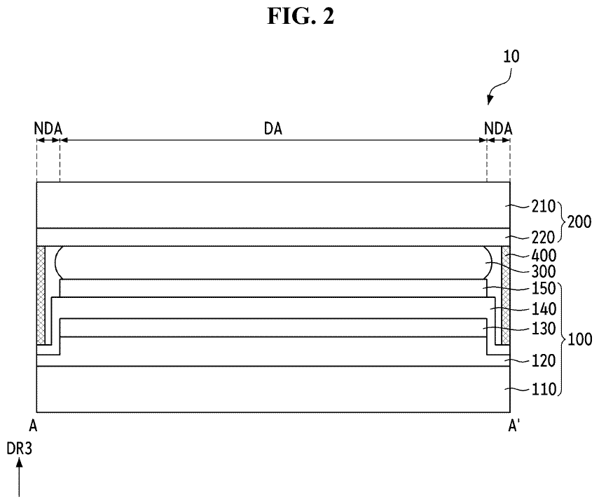

FIG. 2 is a cross-sectional view taken along line A-A′ of FIG. 1. FIG. 3 is a plan view illustrating a display area and a circuit layer of portion B illustrated in FIG. 1.

Referring to FIG. 2, the display device 10 according to some embodiments may include a first substrate 100 and a second substrate 200 facing the first substrate 100.

The display device 10 may further include a filling layer 300 disposed between the first substrate 100 and the second substrate 200. The filling layer 300 may be disposed in the display area DA. The filling layer 300 may fill at least a portion of a space between the first substrate 100 and the second substrate 200. For example, the filling layer 300 may be disposed in at least a portion of the non-display area NDA.

The display device 10 may further include a peripheral sealing layer 400. The peripheral sealing layer 400 may be disposed in the non-display area NDA. The peripheral sealing layer 400 may bond the first substrate 100 and the second substrate 200 to each other.

The first substrate 100 may include a first support substrate 110, an element layer 130 disposed on the first support substrate 110, a sealing layer 140 disposed on the element layer 130, and a color conversion layer 150 disposed on the sealing layer 140.

The first substrate 100 may further include a circuit layer 120 disposed on the first support substrate 110. The element layer 130 may be disposed on the circuit layer 120. Portions of the sealing layer 140 may be disposed directly on the element layer 130 and the circuit layer 120. For example, the sealing layer 140 may be disposed on the circuit layer 120 in the non-display area NDA. The peripheral sealing layer 400 may bond the sealing layer 140 of the first substrate 100 to the second substrate 200.

The first support substrate 110 may include a display area DA from which light for displaying an image may be emitted, and a non-display area NDA disposed around at least a portion of the display area DA and from which light may not be emitted.

Referring to FIG. 3, the display area DA may include light emitting areas EA and a non-light emitting area NEA. Light may be emitted from the light emitting areas EA. The non-light emitting area NEA may be disposed between the light emitting areas EA. The non-light emitting area NEA may surround the light emitting areas EA.

According to some embodiments, the light emitting areas EA may include a first light emitting area EA1 that may emit light in a first wavelength band, a second light emitting area EA2 that may emit light in a second wavelength band lower than the first wavelength band, and a third light emitting area EA3 that may emit light in a third wavelength band lower than the second wavelength band.

As an example, the first wavelength band may be about 600 nm to about 750 nm, and the light in the first wavelength band may be red. The second wavelength band may be about 480 nm to about 560 nm, and the light in the second wavelength band may be green. The third wavelength band may be about 370 nm to about 460 nm, and the light in the third wavelength band may be blue.

Accordingly, a unit pixel PX may display light having a color that is a mixture of light provided by one or more first light emitting areas EA1, one or more second light emitting areas EA2, and one or more third light emitting areas EA3 adjacent to each other among the light emitting areas EA. For example, a unit pixel PX may display white light.

According to an embodiment, each of the first light emitting area EA1, the second light emitting area EA2, and the third light emitting area EA3 may be arranged in parallel in the second direction DR2. Unit pixels PX may disposed adjacent to each other in the first direction DR1 and the second direction DR2. For example, adjacent ones of the first light emitting areas EA1 may be arranged in a line in the second direction DR2, adjacent ones of the second light emitting areas EA2 may be arranged in a line in the second direction DR2, and adjacent ones of the third light emitting areas EA3 may be arranged in a line in the second direction DR2.

In addition, the third light emitting area EA3 may be disposed between the first light emitting area EA1 and the second light emitting area EA2 in the first direction DR1.

Each of the emitting areas EA may have the shape of a rectangle, a triangle, a rhombus, a square, a trapezoid, a circle, or an ellipse.

According to an embodiment, the third light emitting area EA3 may have a smaller dimension in the second direction DR2 than the first light emitting area EA1 and the second light emitting area EA2. Accordingly, in the second direction DR2, a gap between adjacent ones of the third light emitting areas EA3 may be greater than a gap between adjacent ones of the first light emitting areas EA1 and a gap between adjacent ones of the second light emitting areas EA2.

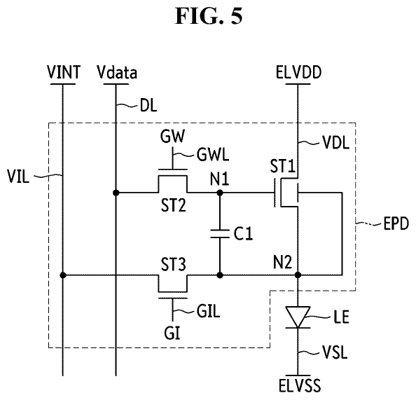

The circuit layer 120 of the first substrate 100 may include light emitting pixel driver EPD arranged in parallel to each other, and lines (VDL, DL, VIL, GWL, GIL in FIG. 5) electrically connected to the light emitting pixel drivers EPD. The lines VDL, DL, VIL, GWL, and GIL may transmit voltage or power signals to each of the light emitting pixel drivers EPD.

The light emitting pixel drivers EPD may include a first light emitting pixel driver EPD1 electrically connected to a light emitting element LE (see FIG. 5) in the first light emitting area EA1, a second light emitting pixel driver EPD2 electrically connected to a light emitting element LE in the second light emitting area EA2, and a third light emitting pixel driver EPD3 electrically connected to a light emitting element LE in the third light emitting area EA3.

As illustrated in FIG. 2, the element layer 130 of the first substrate 100 may include light emitting elements LE of FIG. 5 disposed in the light emitting areas EA.

According to some embodiments, the light emitting elements LE may emit light in a fourth wavelength band, which may be smaller than or equal to the third wavelength band.

The light emitting elements LE of the element layer 130 may be electrically connected to the light emitting pixel drivers EPD of the circuit layer 120, respectively.

The sealing layer 140 may include an inorganic insulating layer and an organic insulating layer. For example, the sealing layer 140 may include two or more inorganic insulating layers including an inorganic insulating material, and at least one organic insulating layer disposed between the two or more inorganic insulating layers and including an organic insulating material.

The sealing layer 140 may inhibit or prevent defects in the circuit layer 120 or the element layer 130 due to the introduction of foreign substances. The sealing layer 140 may inhibit or prevent oxygen or moisture from permeating into the circuit layer 120 or the element layer 130.

The color conversion layer 150 may convert the wavelength band of light emitted from the light emitting elements LE of the element layer 130.

That is, the color conversion layer 150 may convert light emitted from the light emitting element LE in the first light emitting area EA1 from the fourth wavelength band to the first wavelength band, convert light emitted from the light emitting element LE in the second light emitting area EA2 from the fourth wavelength band to the second wavelength band, and transmit and scatter light emitted from the light emitting element LE in the third light emitting area EA3.

The second substrate 200 may include a second support substrate 210 and a color filter layer 220. The second support substrate 210 may face the first support substrate 110. The second support substrate 210 may include light emitting areas EA and non-light emitting areas NEA. The color filter layer 220 may be disposed on a surface of the second support substrate 210. The color filter layer 220 may be disposed on a surface of the second support substrate 210 facing the first support substrate 110.

The color filter layer 220 may transmit light through the light emitting areas EA. The color filter layer 220 may transmit light in some wavelength bands among the light emitted from the color conversion layer 150 of the first substrate 100 through the light emitting areas EA.

That is, the color filter layer 220 may transmit light in the first wavelength band through the first light emitting area EA1, transmit light in the second wavelength band through the second light emitting area EA2, and transmit light in the third wavelength band through the third light emitting area EA3.

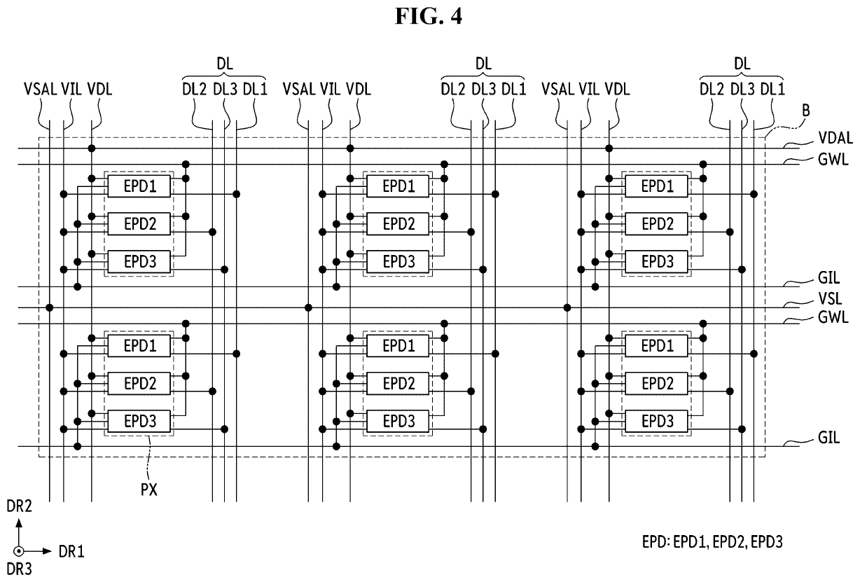

FIG. 4 is a block diagram illustrating the circuit layer of portion B illustrated in FIG. 1. FIG. 5 is an equivalent circuit diagram illustrating a light emitting pixel driver of FIG. 4.

Referring to FIG. 4, the circuit layer 120 of the first substrate 100 of the display device 10 according to some embodiments may include light emitting pixel drivers EPD electrically connected to the light emitting elements LE of the light emitting areas EA, respectively.

The light emitting pixel drivers EPD may include a first light emitting pixel driver EPD1 electrically connected to the light emitting element LE in the first light emitting area EA1, a second light emitting pixel driver EPD2 electrically connected to the light emitting element LE in the second light emitting area EA2, and a third light emitting pixel driver EPD3 electrically connected to the light emitting element LE in the third light emitting area EA3.

The circuit layer 120 may further include a scan write line GWL, a scan initialization line GIL, a data line DL, an initialization voltage line VIL, a first power line VDL, and a second power line VSL. The scan write line GWL may transmit a scan write signal (GW in FIG. 5) to the light emitting pixel drivers EPD, the scan initialization line GIL may transmit a scan initialization signal (GI in FIG. 5) to the light emitting pixel drivers EPD, the data line DL may transmit a data signal (Vdata in FIG. 5) to the light emitting pixel drivers EPD, and the initialization voltage line VIL may transmit an initialization voltage (VINT in FIG. 5) to the light emitting pixel drivers EPD. The first power line VDL may transmit a first power (ELVDD of FIG. 5) to the light emitting pixel drivers EPD, and the second power line VSL may transmit a second power (ELVSS in FIG. 5) to the light emitting elements (LE in FIG. 5).

The circuit layer 120 may further include a first power additional line VDAL and a second power additional line VSAL. The first power additional line VDAL may reduce resistance of the first power line VDL. The second power additional line VSAL may reduce resistance of the second power line VSL.

The first power additional line VDAL may extend in a direction intersecting the first power line VDL and may be electrically connected to the first power line VDL.

The second power additional line VSAL may extend in a direction intersecting the second power line VSL and may be electrically connected to the second power line VSL.

The data lines DL may include a plurality of data lines. The data lines DL may include a first data line DL1 that transmits a data signal (Vdata in FIG. 5) of the first light emitting pixel driver EPD1, a second data line DL2 that transmits a data signal (Vdata in FIG. 5) of the second light emitting pixel driver EPD2, and a third data line DL3 that transmits a data signal (Vdata in FIG. 5) of the third light emitting pixel driver EPD3.

Referring to FIG. 5, the light emitting pixel driver EPD may be electrically connected between the first power ELVDD and the light emitting element LE, and the light emitting element LE may be electrically connected between the light emitting pixel driver EPD and the second power ELVSS.

The light emitting element LE may be an organic light emitting diode (LED) including an organic light emitting layer, a quantum dot LED including a quantum dot light emitting layer, a micro LED, or an inorganic LED including an inorganic semiconductor.

The second power ELVSS may have a lower voltage level than the first power ELVDD.

An anode electrode of the light emitting element LE may be electrically connected to the light emitting pixel driver EPD, and a cathode electrode of the light emitting element LE may be electrically connected to the second power ELVSS.

The light emitting pixel driver EPD may include a plurality of transistors and a and a capacitor C1. The light emitting pixel driver EPD may include a first transistor ST1 and one or more of a second transistor ST2 or a third transistor ST3. The light emitting pixel driver EPD may include one or more capacitors C1 electrically connected to the first transistor ST1. The first transistor ST1 may generate a driving current for a light emitting element LE.

The first transistor ST1 may be electrically connected between the first power line VDL and second node N2. The first transistor ST1 may be electrically connected between the first power line VDL and second node N2 and the light emitting element LE.

A first electrode of the first transistor ST1 may be electrically connected to the first power line VDL.

A second gate electrode of the first transistor ST1 may be electrically connected to the second node N2. The second electrode of the first transistor ST1 may be electrically connected to the second node N2 and the anode electrode of the light emitting element LE.

A first gate electrode of the first transistor ST1 may be electrically connected to a first node N1 and the second transistor ST2.

The second transistor ST2 may be electrically connected between the data line DL and the first node N1.

A gate electrode of the second transistor ST2 may be electrically connected to the scan write line GWL. The second transistor ST2 may be turned on by the scan write signal of the scan write line GWL.

When the second transistor ST2 is turned on, the data signal Vdata of the data line DL may be transmitted to the first node N1.

A voltage difference between the gate electrode of the first transistor ST1 and the first electrode of the first transistor ST1, which may be a voltage difference between a gate and a source, may become greater than a threshold voltage of the first transistor ST1. The voltage difference between the gate electrode of the first transistor ST1 and the first electrode of the first transistor ST1 may be a voltage difference between the first power ELVDD and the data signal Vdata when the data signal Vdata is transmitted to the first node N1. When the data signal Vdata is transmitted to the first node N1, the first transistor ST1 may be turned on, and a source-drain current having a size corresponding to the data signal Vdata may be generated between the first electrode and the second electrode of the first transistor ST1. In addition, the source-drain current of the first transistor ST1 may be supplied as a driving current to the light emitting element LE.

In a case where the driving current corresponds to the data signal Vdata and is supplied to the light emitting element LE, the light emitting element LE may emit light with luminance corresponding to the data signal Vdata.

The first capacitor C1 may be electrically connected between the first node N1 and the second node N2.

The first capacitor C1 may be charged by the data signal Vdata transmitted to the first node N1 through the turned-on of the second transistor ST2.

Accordingly, a potential of the first node N1 may be maintained for a predetermined period of time due to a voltage charge of the first capacitor C1.

The third transistor ST3 may be electrically connected between the initialization voltage line VIL and the second node N2.

A gate electrode of the third transistor ST3 may be connected to the scan initialization line GIL. That is, the third transistor ST3 may be turned on by the scan initialization signal GI of the scan initialization line GIL.

When the third transistor ST3 is turned on, a potential of the second node N2, that is, a potential of the anode electrode of the light emitting element LE, may be initialized to the initialization voltage VINT of the initialization voltage line VIL.

As illustrated in FIG. 5, according to an embodiment, each of the first, second and third transistors ST1, ST2, and ST3 may be an N-type MOSFET. However, this is only an example, and at least one of the first, second or third transistors ST1, ST2, and ST3 may be a P-type MOSFET.

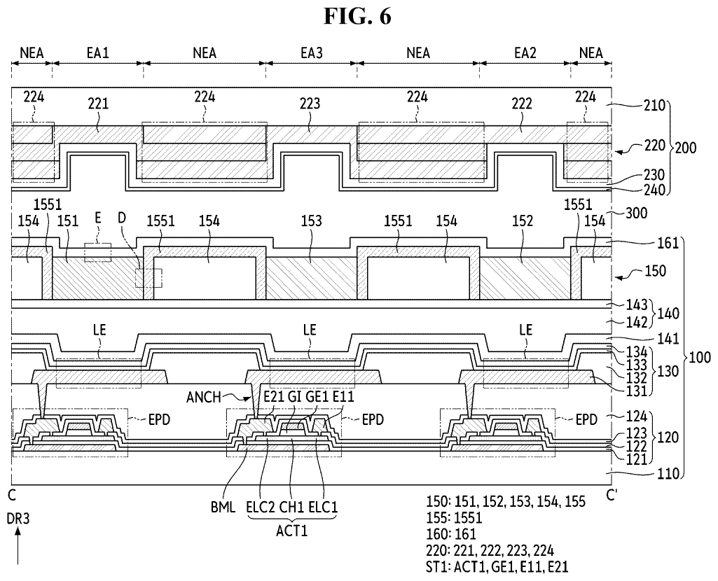

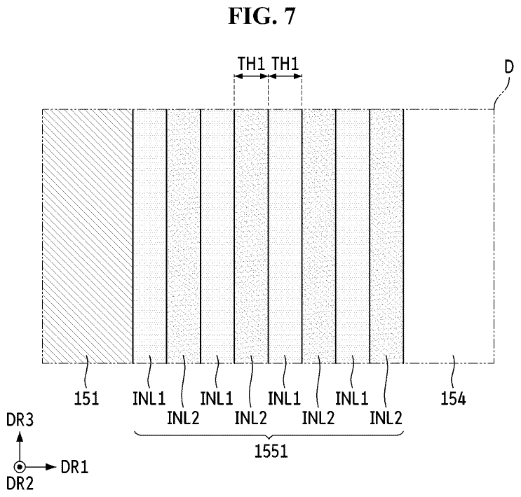

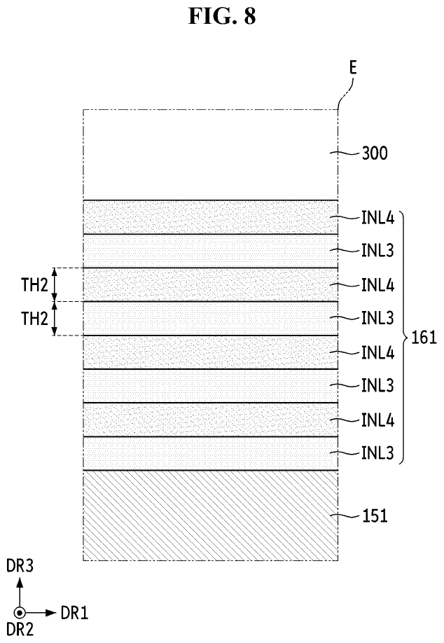

FIG. 6 is a cross-sectional view taken along line C-C′ of FIG. 3. FIG. 7 is an enlarged view illustrating portion D of FIG. 6 according to an embodiment. FIG. 8 is an enlarged view illustrating portion E of FIG. 6 according to an embodiment.

Referring to FIG. 6, the first substrate 100 of the display device 10 according to some embodiments may include a first support substrate 110, an element layer 130, a sealing layer 140, and a color conversion layer 150. The element layer 130 may be disposed on the first support substrate 110, the sealing layer 140 may be disposed on the element layer 130, and the color conversion layer 150 may be disposed on the sealing layer 140.

According to some embodiments, the first substrate 100 may further include a circuit layer 120. The circuit layer 120 may be disposed on the first support substrate 110. Accordingly, the element layer 130 may be disposed on the circuit layer 120.

According to some embodiments, the first substrate 100 may further include a color conversion capping layer 160. The color conversion capping layer 160 may be disposed covering the color conversion layer 150.

The first support substrate 110 may include a display area (DA in FIG. 1) and a non-display area (NDA in FIG. 1). The display area DA may include light emitting areas (EA: EA1, EA2, and EA3 in FIG. 3) arranged in parallel to each other, and a non-light emitting area NEA between the light emitting areas EA.

The circuit layer 120 may include a buffer layer 121, a first interlayer insulating layer 122, a second interlayer insulating layer 123, and a planarization layer 124. The buffer layer 121 may be disposed on the first support substrate 110, the first interlayer insulating layer 122 may be disposed on the buffer layer 121, the second interlayer insulating layer 123 may be disposed on the first interlayer insulating layer 122, and the planarization layer 124 may be disposed on the second interlayer insulating layer 123.

Each of the buffer layer 121, the first interlayer insulating layer 122, and the second interlayer insulating layer 123 may include an inorganic insulating material.

The planarization layer 124 may include an organic insulating material.

The circuit layer 120 may include light emitting pixel drivers EPD that may transmit a driving current to light emitting elements LE.

Each of the light emitting pixel drivers EPD may include two or more transistors. Each of the light emitting pixel drivers EPD may include two or more of the first to third transistors ST1, ST2, or ST3 in FIG. 5.

The first transistor ST1 of each of the light emitting pixel drivers EPD may include an active layer ACT1, a gate electrode GE1, and a first electrode E11 and a second electrode E21. The active layer ACT1 may be disposed on the buffer layer 121, the gate electrode GE1 may be disposed on a gate insulating layer GI covering a channel portion CH1 of the active layer ACT1, and the first electrode E11 and the second electrode E21 may be disposed on the first interlayer insulating layer 122 covering the active layer ACT1 and the gate electrode GE1.

The active layer ACT1 may overlap a light blocking layer BML on the first support substrate 110.

The buffer layer 121 may cover the light blocking layer BML.

The active layer ACT1 may include a channel portion CH1, a first electrode portion ELC1 connected to a first side of the channel portion CH1, and a second electrode portion ELC2 connected to a second side of the channel portion CH1.

The gate insulating layer GI may include an inorganic insulating material.

The first electrode E11 may be electrically connected to the first electrode portion ELC1 of the active layer ACT1. The first electrode E11 may be electrically connected to the first electrode portion ELC1 of the active layer ACT1 through a hole penetrating through the first interlayer insulating layer 122.

The second electrode E21 may be electrically connected to the second electrode portion ELC2 of the active layer ACT1. The second electrode E21 may be electrically connected to the second electrode portion ELC2 of the active layer ACT1 through a hole penetrating through the first interlayer insulating layer 122.

The second electrode E21 may be electrically connected to the light blocking layer BML. The second electrode E21 may be electrically connected to the light blocking layer BML through a hole penetrating through the first interlayer insulating layer 122 and the buffer layer 121.

In the case that the light blocking layer BML faces a rear surface of the active layer ACT1, a portion of the active layer ACT1 adjacent to the light blocking layer BML may be less activated than another portion adjacent to the gate electrode GE1 depending on a potential of the same light blocking layer BML as the second electrode E21.

The second interlayer insulating layer 123 may cover the first interlayer insulating layer 122, the first electrode E11, and the second electrode E21.

The element layer 130 may be disposed on the planarization layer 124′.

The element layer 130 includes light emitting elements LE disposed in light emitting areas EA. The light emitting elements LE may emit light in the fourth wavelength band.

Each of the light emitting elements LE may include a structure in which a light emitting layer 133 may be disposed between an anode electrode 131 and a cathode electrode 134 that face each other.

The element layer 130 may include anode electrodes 131, a pixel defining layer 132, a light emitting layer 133, and a cathode electrode 134. That is, the element layer 130 may include anode electrodes 131 disposed in the light emitting areas EA, the pixel defining layer 132 disposed in the non-light emitting area NEA and covering edge portions of the anode electrodes 131, the light emitting layer 133 disposed on the anode electrodes 131 and the pixel defining layer 132, and the cathode electrode 134 disposed on the light emitting layer 133.

As another example, the light emitting layer 133 may be disposed in each of the light emitting areas EA.

The anode electrodes 131 may be electrically connected to the light emitting pixel drivers EPD through an anode connection hole ANCH.

That is, the anode electrode 131 may be electrically connected to the second electrode E21 of the first transistor ST1 of the light emitting pixel driver EPD through the anode connection hole ANCH.

The anode connection hole ANCH may penetrate through the planarization layer 124 and the second interlayer insulating layer 123.

The sealing layer 140 may include a first sealing layer 141, a second sealing layer 142, and a third sealing layer 143. The first sealing layer 141 may be disposed on the element layer 130 and including an inorganic insulating material, the second sealing layer 142 may be disposed on the first sealing layer 141 and including an organic insulating material, and the third sealing layer 143 may be disposed on the second sealing layer 142 and including an inorganic insulating material.

The color conversion layer 150 may include a partition wall 154 and a reflective wall 155. The partition wall 154 may be disposed in the non-light emitting area NEA and the reflective wall 155 may cover a side surface of the partition wall 154.

The color conversion layer 150 may further include a first color conversion portion 151, a second color conversion portion 152, and a light transmitting portion 153. The first color conversion portion 151 may be disposed in the first light emitting area EA1, the second color conversion portion 152 may be disposed in the second light emitting area EA2, and the light transmitting portion 153 may be disposed in the third light emitting area EA3.

The first color conversion portion 151 may convert light in the fourth wavelength band emitted from the light emitting element LE in the first light emitting area EA1 into light in the first wavelength band.

The first color conversion portion 151 may be a cured product of a first ink material including a base resin and first color conversion particles dispersed within the base resin. The first color conversion particle may convert light in the fourth wavelength band into light in the first wavelength band.

The second color conversion portion 152 may convert light in the fourth wavelength band emitted from the light emitting element LE in the second light emitting area EA2 into light in the second wavelength band.

The second color conversion portion 152 may be a cured product of a second ink material including a base resin and second color conversion particles dispersed within the base resin. The second color conversion particle may convert light in the fourth wavelength band into light in the second wavelength band.

The light transmitting portion 153 may transmit and scatter light in the fourth wavelength band emitted from the light emitting element LE in the third light emitting area EA3.

The light transmitting portion 153 may include a base resin and scattering particles dispersed within the base resin.

The scattering particles may be metal oxide particles or organic particles.

The metal oxide particles may be at least one of titanium oxide (TiO₂), zirconium oxide (ZrO₂), aluminum oxide (Al₂O₃), indium oxide (In₂O₃), zinc oxide (ZnO), or tin oxide (SnO₂).

The organic particles may be acrylic resin or urethane resin.

Each of the first color conversion portion 151 and the second color conversion portion 152 may further include scattering particles dispersed within the base resin.

Each of the first color conversion particle and the second color conversion particle may be at least one of a quantum dot, a quantum rod, or a phosphor.

The quantum dot may be selected from any one of group IV nanocrystals, group II-VI compound nanocrystals, group III-V compound nanocrystals, or group IV-VI nanocrystals, or combinations thereof.

As an example, the quantum dots may be photo-active, capable of absorbing and then emitting light. A color of light that a quantum dot emits may depend on a size of the quantum dot. For example, a quantum dot with a core diameter of between about 6 and 7 nanometers may emit red.

The first color conversion portion 151, the second color conversion portion 152 and the light transmitting portion 153 may include the same base resin or may include different base resins.

The partition wall 154 may be disposed between adjacent ones of the first color conversion portion 151, the second color conversion portion 152, and the light transmitting portion 153.

The partition wall 154 may include an organic material.

The reflective wall 155 may cover a surface of the partition wall 154. The reflective wall 155 may cover a side surface of the partition wall 154.

That is, the reflective wall 155 may be disposed between each of the first color conversion portion 151, the second color conversion portion 152, and the light transmitting portion 153 and the partition wall 154.

According to an embodiment, the reflective wall 155 may cover an upper portion of the partition wall 154. The reflective wall 155 may continually cover the side surfaces and the upper portion of the partition wall 154.

According to some embodiments, the reflective wall 155 may include a first reflective wall portion 1551 disposed in at least a portion of the non-light emitting area NEA.

Referring to FIG. 7, the first reflective wall portion 1551 may include first inorganic layers INL1 and second inorganic layers INL2. The first inorganic layers INL1 and second inorganic layers INL2 may be disposed alternately with each other.

An inorganic layer of the second inorganic layers INL2 may be in contact with the partition wall 154. Alternatively, an inorganic layer of the first inorganic layers INL1 may be in contact with the partition wall 154. An inorganic layer of the first inorganic layers INL1 may be in contact with the first color conversion portion 151.

Each of the first inorganic layers INL1 may have a refractive index of about 1.7 to about 2.0.

Each of the first inorganic layers INL1 may include an inorganic insulating material that may be deposited in an environment of about 200° C. or less.

As an example, each of the first inorganic layers INL1 may include silicon nitride (SiNx).

The second inorganic layers INL2 may include a material different from the material of the first inorganic layers INL1. For example, the first inorganic layers INL1 may have a first refractive index and the second inorganic layers INL2 may have a second refractive index, wherein the first refractive index and the second refractive index may be different from each other.

That is, each of the second inorganic layers INL2 may have a refractive index of about 1.48 to about 1.6.

Each of the second inorganic layers INL2 may include an inorganic insulating material that may be deposited in an environment of about 200° C. or less.

As an example, each of the second inorganic layers INL2 may include silicon oxide (SiOx) or silicon oxynitride (SiON).

In this way, light in some wavelength bands may resonate in each of the first inorganic layers INL1 and the second inorganic layers INL2, and may be reflected at interfaces between the first inorganic layers INL1 and the second inorganic layers INL2 where the refractive indices abruptly change. For example, when light encounters a boundary between the first inorganic layers INL1 and the second inorganic layers INL2 having different refractive indexes, part of the light may be reflected at the interface, and part of the light may be transmitted through the interface. An amount of reflection and transmission may depend on the refractive index contrast.

As an example, each of the first inorganic layers INL1 and the second inorganic layers INL2 may be disposed with a first thickness TH1 corresponding to a first wavelength band of red light or a second wavelength band of green light.

The first thickness TH1 may be selected to correspond to a first wavelength band of red light or a second wavelength band of green light in the inorganic materials of the first inorganic layers INL1 and the second inorganic layers INL2. The wavelength of light in a given material may depend on the material's refractive index. The wavelength of light may be shortend in materials with a refractive index greater than 1.

The first thickness TH1 may be about 95 nanometers (nm) to about 105 nm.

As illustrated in FIG. 6, according to an embodiment, the reflective wall 155 may be formed of the first reflective wall portion 1551.

That is, the first reflective wall portion 1551 may be disposed between each of the first color conversion portion 151, the second color conversion portion 152, and the light transmitting portion 153 and the partition wall 154.

As described herein, according to some embodiments, the reflective wall 155 may not include a reflective metal material. The reflective wall 155 may include the first reflective wall portion 1551 having a structure in which the first inorganic layers INL1 and the second inorganic layers INL2 are alternately disposed. Each of the first inorganic layers INL1 and the second inorganic layers INL2 includes an inorganic material that may be laminated in a low-temperature environment, and a process in a high-temperature environment for disposing the color conversion layer may be avoided. In a case where the color conversion layer may be formed in a low-temperature environment, for example, less than about 200° C., damage to the sealing layer 140 and the element layer 130 may be reduced or eliminated, and the lifespan and yield of the display device 10 may be improved.

In addition, in a case that the reflective wall 155 includes the first inorganic layers INL1 and the second inorganic layers INL2, each made of the insulating inorganic material, rather than the reflective metal material, the concentration of static electricity due to the conductivity of the reflective wall 155 may be inhibited or prevented, even if the reflective wall 155 covers the upper and side surfaces of the partition wall 154. That is, the partition wall 154 may be protected by the reflective wall 155, and damage to the element layer 130, the sealing layer 140, and the color conversion layer 150 due to electrical shock may be reduced or eliminated.

As illustrated in FIG. 6, according to some embodiments, the first substrate 100 may include a color conversion capping layer 160. The color conversion capping layer 160 may cover the color conversion layer 150.

The color conversion capping layer 160 may include a first color conversion capping portion 161. The first color conversion capping portion 161 may be disposed in at least some of the light emitting areas EA and the non-light emitting area NEA.

Referring to FIG. 8, the first color conversion capping portion 161 may include third inorganic layers INL3 and fourth inorganic layers INL4. The third inorganic layers INL3 and the fourth inorganic layers INL4 may be disposed alternately with each other.

An inorganic layer of the third inorganic layers INL3 may be in contact with the color conversion layer 150 (shown as the first color conversion portion 151 in FIG. 8).

Each of the third inorganic layers INL3 may have a refractive index of about 1.48 to about 1.6.

Each of the third inorganic layers INL3 may include an inorganic insulating material that may be deposited in an environment of about 200° C. or less.

As an example, each of the third inorganic layers INL3 may include silicon oxide (SiOx) or silicon oxynitride (SiON).

The fourth inorganic layers INL4 may include a material different from the material of the third inorganic layers INL3. For example, the third inorganic layers INL3 may have a third refractive index and the fourth inorganic layers INL4 may have a fourth refractive index, wherein the third refractive index and the fourth refractive index may be different from each other.

That is, each of the fourth inorganic layers INL4 may have a refractive index of about 1.7 to about 2.0.

Each of the fourth inorganic layers INLA may include an inorganic insulating material that may be deposited in an environment of about 200° C. or less.

As an example, each of the fourth inorganic layers INL4 may include silicon nitride (SiNx).

In this way, light in some wavelength bands may resonate in each of the third inorganic layers INL3 and the fourth inorganic layers INL4, and may be reflected at interfaces between the third inorganic layers INL3 and the fourth inorganic layers INL4 where the refractive indices abruptly change.

As an example, each of the third inorganic layers INL3 and the fourth inorganic layers INL4 may be disposed with a second thickness TH2 corresponding to the third wavelength band of blue light or the fourth wavelength band which may be smaller than or equal to the third wavelength band.

The second thickness TH2 may be less than the first thickness TH1.

As an example, the second thickness TH2 may be about 65 nm to about 75 nm.

In this way, the light in the third wavelength band or the fourth wavelength band may be partially reflected by the first color conversion capping portion 161 and incident on the color conversion layer 150, which may improve light emission efficiency. Therefore, since a light emission efficiency of the color conversion layer 150 and the color conversion capping layer 160 may be improved, the luminance of the display device 10 may be improved.

As illustrated in FIG. 6, the color conversion capping layer 160 may be formed of a first color conversion capping portion 161.

That is, the first color conversion capping portion 161 may be disposed in the first light emitting area EA1, the second light emitting area EA2, the third light emitting area EA3, and the non-light emitting area NEA.

According to some embodiments, the second substrate 200 of the display device 10 may include a second support substrate 210, a color filter layer 220, and a filter capping layer 230. The color filter layer 220 may be disposed on a surface of the second support substrate 210, and the filter capping layer 230 may cover the color filter layer 220.

In the third direction DR3, which may be the direction in which light of the display device 10 is emitted, the color filter layer 220 may be disposed on the color conversion layer 150, and the second support substrate 210 may be disposed on the color filter layer 220. Accordingly, light emitted from the light emitting elements LE of the element layer 130 may pass through the color conversion layer 150, the color filter layer 220, and the second support substrate 210 and may be emitted to the outside.

The color filter layer 220 may include a first filter portion 221, a second filter portion 222, a third filter portion 223, and a light blocking portion 224. The first filter portion 221 may be disposed in the first light emitting area EA1 and may transmit light in the first wavelength band, the second filter portion 222 may be disposed in the second light emitting area EA2 and may transmit light in the second wavelength band, the third filter portion 223 may be disposed in the third light emitting area EA3 and may transmit light in the third wavelength band, and the light blocking portion 224 may define the non-light emitting area NEA. The light blocking portion 224 may block light incident on the light blocking portion 224.

Each of the first filter portion 221, the second filter portion 222, and the third filter portion 223 may include a colorant such as a dye or pigment. The colorant may be a material that absorbs light in wavelength bands other than a predetermined wavelength band.

For example, the first filter portion 221 may include a colorant that absorbs light in wavelength bands other than the first wavelength band among the light transmitted through the color conversion layer 150, and the light in the first wavelength band may be transmitted.

The second filter portion 222 may include a colorant that absorbs light in wavelength bands other than the second wavelength band among the light transmitted through the color conversion layer 150, and the light in the second wavelength band may be transmitted.

The third filter portion 223 may include a colorant that absorbs light in wavelength bands other than the third wavelength band among the light transmitted through the color conversion layer 150, and the light in the third wavelength band may be transmitted.

The light blocking portion 224 may include a structure in which two or more filter portions among the first filter portion 221, the second filter portion 222, and the third filter portion 223 are laminated.

Alternatively, the light blocking portion 224 may also include a material that absorbs light, such as a black matrix material.

The filter capping layer 230 may cover the color filter layer 220 and may include an inorganic insulating material.

The second substrate 200 may further include a low refractive index layer 240 disposed between the color filter layer 220 and the color conversion layer 150. The low refractive index layer 240 may include an organic material having a refractive index of about 1.1 or more and about 1.4 or less.

As an example, the low refractive index layer 240 may be disposed on the filter capping layer 230.

According to some embodiments, the display device 10 may further include a filling layer 300 disposed between the first substrate 100 and the second substrate 200.

The filling layer 300 may fill a space between the first substrate 100 and the second substrate 200.

The filling layer 300 may be disposed between the color conversion capping layer 160 of the first substrate 100 and the filter capping layer 230 of the second substrate 200.

The filling layer 300 may include an organic material having light transmitting properties and adhesive properties.

As an example, the filling layer 300 may include a Si-based organic material or an epoxy-based organic material.

As illustrated in FIG. 6, the first reflective wall portion 1551 may be omitted a reflective metal material. The first reflective wall portion 1551 may be formed without depositing a reflective metal material. For example, the first reflective wall portion 1551 may be formed in a relatively low-temperature environment having a temperature less than a temperature that may be used to deposit a reflective metal material.

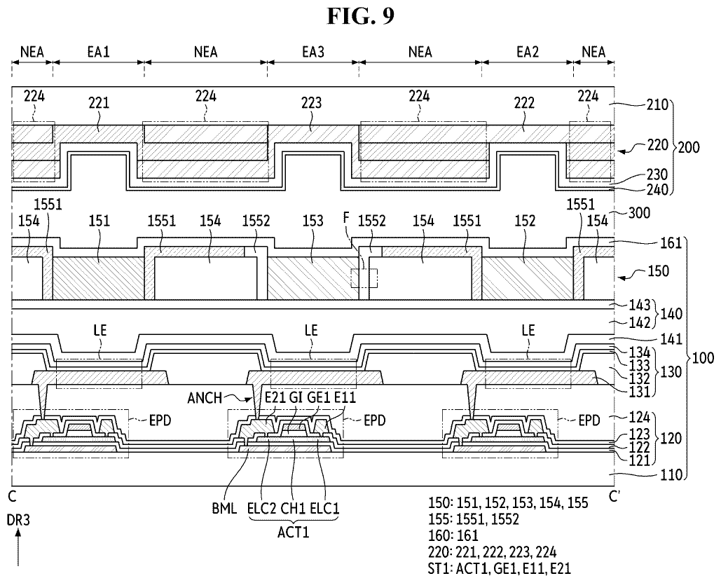

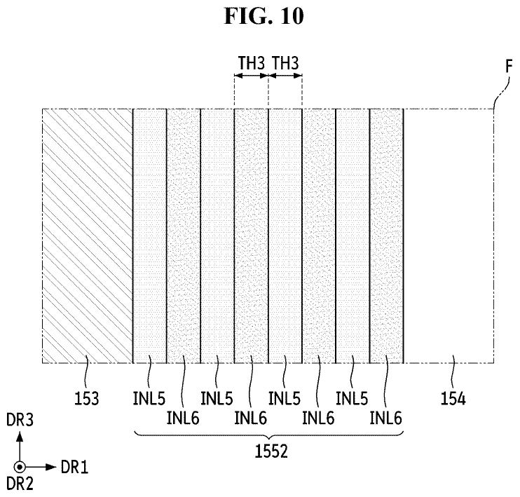

FIG. 9 is a cross-sectional view taken along line C-C′ of FIG. 3 according to an embodiment. FIG. 10 is an enlarged view illustrating portion F of FIG. 9.

A display device 10 according to an embodiment illustrated in FIG. 9 may be substantially the same as the display device 10 according to some embodiments illustrated in FIGS. 1 to 8 and a duplicate description thereof may be omitted below. In a display device 10 according to an embodiment illustrated in FIG. 9 the reflective wall 155 may include a second reflective wall portion 1552 disposed between the light transmitting portion 153 and the partition wall 154.

According to an embodiment illustrated in FIG. 9, the reflective wall 155 may include a first reflective wall portion 1551 disposed between each of the first color conversion portion 151 and the second color conversion portion 152 and the partition wall 154, and a second reflective wall portion 1552 disposed between the light transmitting portion 153 and the partition wall 154.

Referring to FIG. 10, the second reflective wall portion 1552 may include fifth inorganic layers INL5 and sixth inorganic layers INL6. The fifth inorganic layers INL5 and the sixth inorganic layers INL6 may be disposed alternately with each other.

An inorganic layer of the sixth inorganic layers INL6 may be in contact with the partition wall 154. Alternatively, an inorganic layer of the fifth inorganic layers INL5 may be in contact with the partition wall 154. An inorganic layer of the sixth inorganic layers INL6 may be in contact with the light transmitting portion 153.

Each of the fifth inorganic layers INL5 may have a refractive index of about 1.7 to about 2.0.

Each of the fifth inorganic layers INL5 may include an inorganic insulating material that may be deposited in an environment of about 200° C. or less.

As an example, each of the fifth inorganic layers INL5 may include silicon nitride (SiNx).

The sixth inorganic layers INL6 may include a material different from the material of the fifth inorganic layers INL5. For example, the fifth inorganic layers INL5 may have a fifth refractive index and the sixth inorganic layers INL6 may have a sixth refractive index, wherein the fifth refractive index and the sixth refractive index may be different from each other.

That is, each of the sixth inorganic layers INL6 may have a refractive index of about 1.48 to about 1.6.

Each of the sixth inorganic layers INL6 may include an inorganic insulating material that may be deposited in an environment of about 200° C. or less.

As an example, each of the sixth inorganic layers INL6 may include silicon oxide (SiOx) or silicon oxynitride (SiON).

In this way, light in some wavelength bands may resonate in each of the fifth inorganic layers INL5 and the sixth inorganic layers INL6, and may be reflected at interfaces between the fifth inorganic layers INL5 and the sixth inorganic layers INL6 where the refractive indices abruptly change.

As an example, each of the fifth inorganic layers INL5 and the sixth inorganic layers INL6 may be disposed with a third thickness TH3 corresponding to the third wavelength band of blue light or the fourth wavelength band which may be smaller than or equal to the third wavelength band.

The third thickness TH3 may be smaller than the first thickness TH1.

As an example, the third thickness TH3 may be about 65 nm to about 75 nm.

In this way, as the light in the third wavelength band or the fourth wavelength band may be reflected within the light transmitting portion 153 by the second reflective wall portion 1552, the light may be scattered and emitted, and a light emission efficiency of the light transmitting portion 153 may be improved.

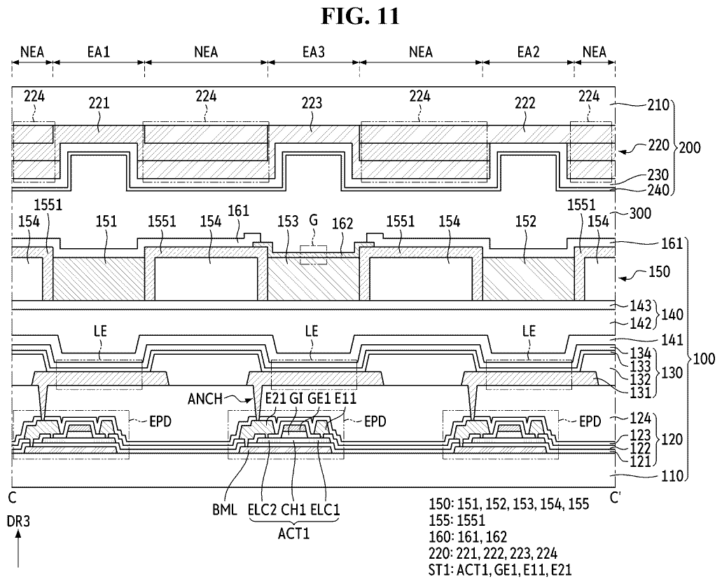

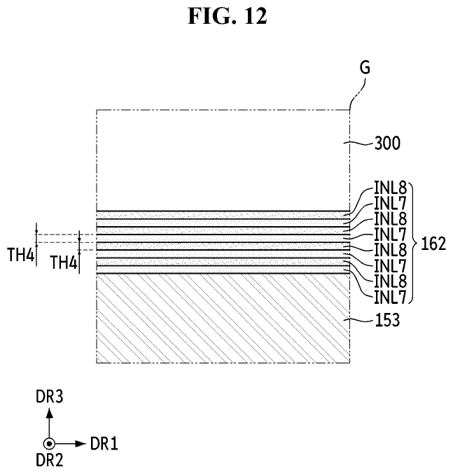

FIG. 11 is a cross-sectional view taken along line C-C′ of FIG. 3 according to an embodiment. FIG. 12 is an enlarged view illustrating portion G of FIG. 11.

Since a display device 10 according to an embodiment illustrated in FIG. 11 is substantially the same as the display device 10 according to some embodiments illustrated in FIGS. 1 to 8 a duplicate description thereof may be omitted below. As shown in FIG. 11, the color conversion capping layer 160 may include a second color conversion capping portion 162 disposed in the third light emitting area EA3.

According to an embodiment illustrated in FIG. 11, the color conversion capping layer 160 may include a first color conversion capping portion 161 disposed in the first light emitting area EA1, the second light emitting area EA2, and the non-light emitting area NEA, and a second color conversion capping portion 162 disposed in the third light emitting area EA3.

The first color conversion capping portion 161 may cover an edge portion of the second color conversion capping portion 162. In this way, a defect in which the partition wall 154 or the reflective wall 155 is exposed by the gap between the first color conversion capping portion 161 and the second color conversion capping portion 162 may be inhibited or prevented.

Referring to FIG. 12, the second color conversion capping portion 162 may include seventh inorganic layers INL7 and eighth inorganic layers INL8 that may be disposed alternately with each other.

An inorganic layer of the seventh inorganic layers INL7 may be in contact with the light transmitting portion 153.

Each of the seventh inorganic layers INL7 may have a refractive index of about 1.48 to about 1.6.

Each of the seventh inorganic layers INL7 may include an inorganic insulating material that may be deposited in an environment of about 200° C. or less.

As an example, each of the seventh inorganic layers INL7 may include silicon oxide (SiOx) or silicon oxynitride (SiON).

The eighth inorganic layers INL8 may include a material different from the material of the seventh inorganic layers INL7. For example, the seventh inorganic layers INL7 may have a seventh refractive index and the eighth inorganic layers INL8 may have a eighth refractive index, wherein the seventh refractive index and the eighth refractive index may be different from each other.

That is, each of the eighth inorganic layers INL8 may have a refractive index of about 1.7 to about 2.0.

Each of the eighth inorganic layers INL8 may include an inorganic insulating material that may be deposited in an environment of about 200° C. or less.

As an example, each of the eighth inorganic layers INL8 may include silicon nitride (SiNx).

In this way, each of the seventh inorganic layers INL7 and the eighth inorganic layers INL8 may be disposed with a fourth thickness TH4 that does not correspond to visible light.

The fourth thickness TH4 may be smaller than the second thickness TH2.

As an example, the fourth thickness TH4 may be about 15 nm to about 25 nm.

In this way, the second color conversion capping portion 162 may transmit light in the third wavelength band without reflecting the light.

That is, as the light in the third wavelength band is reflected to the color conversion layer 150 and reused by the first color conversion capping portion 161 disposed in the first light emitting area EA1 and the second light emitting area EA2, a light emission efficiency of each of the first color conversion portion 151 and the second color conversion portion 152 may be improved, and the light in the third wavelength band may be emitted from the light transmitting portion 153 through the second color conversion capping portion 162 disposed in the third light emitting area EA3.

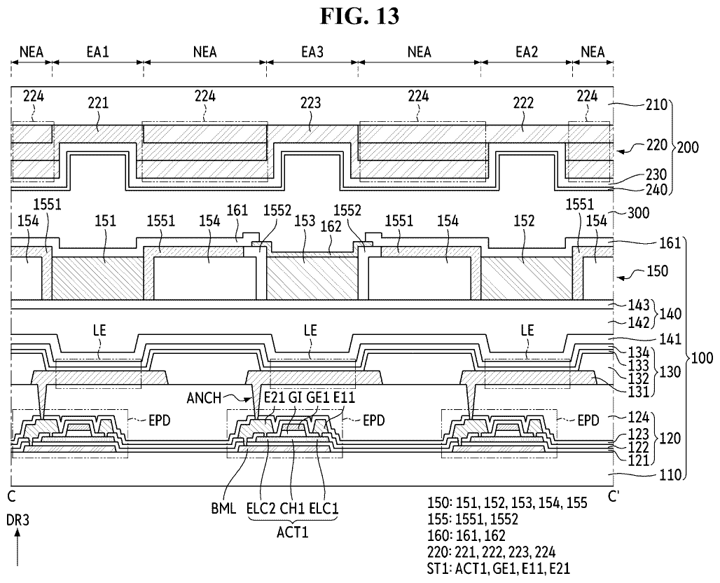

FIG. 13 is a cross-sectional view taken along line C-C′ of FIG. 3 according to an embodiment.

Since a display device 10 according to an embodiment illustrated in FIG. 13 is substantially the same as the display device 10 according to an embodiment illustrated in FIG. 9 and FIG. 10 a duplicate description thereof may be omitted below. As shown in FIG. 13, the color conversion capping layer 160 may include a second color conversion capping portion 162 disposed in the third light emitting area EA3.

Since the second color conversion capping portion 162 according to an embodiment illustrated in FIG. 13 is the same as that of an embodiment illustrated in FIG. 11 and FIG. 12, a duplicate description thereof may be omitted below.

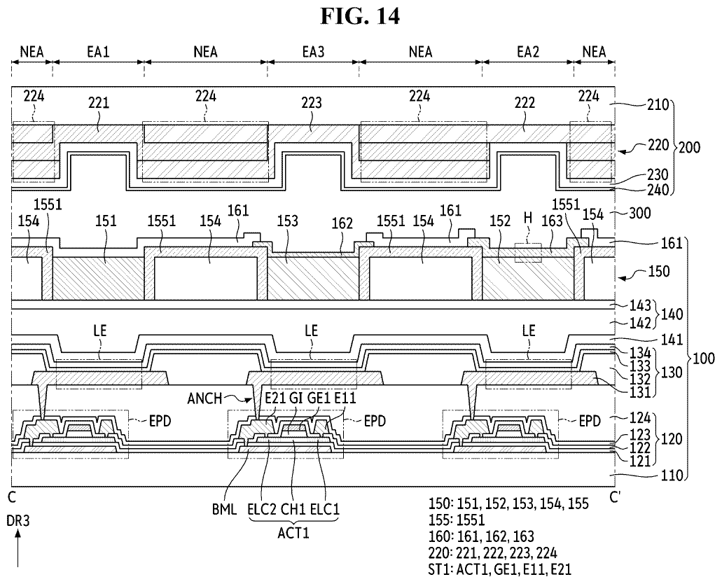

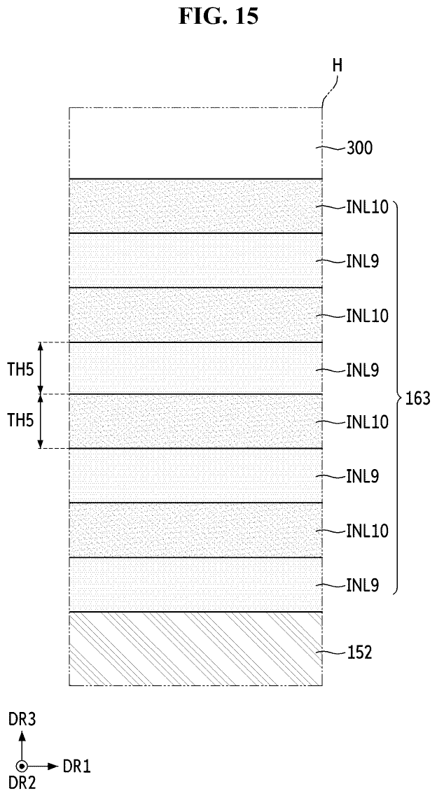

FIG. 14 is a cross-sectional view taken along line C-C′ of FIG. 3 according to an embodiment. FIG. 15 is an enlarged view illustrating portion H of FIG. 14.

Since a display device 10 according to an embodiment illustrated in FIG. 14 is substantially the same as the display device 10 according to an embodiment illustrated in FIG. 11 and FIG. 12 a duplicate description thereof may be omitted below. As shown in FIG. 14, the color conversion capping layer 160 may include a third color conversion capping portion 163 disposed in the second light emitting area EA2.

According to an embodiment illustrated in FIG. 14, the color conversion capping layer 160 may include a first color conversion capping portion 161 disposed in the first light emitting area EA1 and the non-light emitting area NEA, a second color conversion capping portion 162 disposed in the third light emitting area EA3, and a third color conversion capping portion 163 disposed in the second light emitting area EA2.

The first color conversion capping portion 161 may cover an edge portion of each of the second color conversion capping portion 162 and the third color conversion capping portion 163. In this way, a defect in which the partition wall 154 or the reflective wall 155 is exposed by the gap between each of the second color conversion capping portion 162 and the third color conversion capping portion 163 and the first color conversion capping portion 161 may be inhibited or prevented.

Referring to FIG. 15, the third color conversion capping portion 163 may include ninth inorganic layers INL9 and tenth inorganic layers INL10 that may be disposed alternately with each other.

An inorganic layer of the ninth inorganic layers INL9 may be in contact with the second color conversion portion 152.

Each of the ninth inorganic layers INL9 may have a refractive index of about 1.48 to about 1.6.

Each of the ninth inorganic layers INL9 may include an inorganic insulating material that may be deposited in an environment of about 200° C. or less.

As an example, each of the ninth inorganic layers INL9 may include silicon oxide (SiOx) or silicon oxynitride (SiON).

The tenth inorganic layers INL10 may include a material different from the material of the ninth inorganic layers INL9. For example, the ninth inorganic layers INL9 may have a ninth refractive index and the tenth inorganic layers INL10 may have a tenth refractive index, wherein the ninth refractive index and the tenth refractive index may be different from each other.

That is, each of the tenth inorganic layers INL10 may have a refractive index of about 1.7 to about 2.0.

Each of the tenth inorganic layers INL10 may include an inorganic insulating material that may be deposited in an environment of about 200° C. or less.

As an example, each of the tenth inorganic layers INL10 may include silicon nitride (SiNx).

In this way, each of the ninth inorganic layers INL9 and the tenth inorganic layers INL10 may be disposed with a fifth thickness TH5 that corresponds to the third wavelength band. The fifth thickness TH5 may be greater than the first thickness TH1.

As an example, the fifth thickness TH5 may be about 195 nm to about 205 nm.

In this way, the third color conversion capping portion 163 may transmit the light in the second wavelength band and reflect the light in the third wavelength band to the second color conversion portion 152. Therefore, a light emission efficiency of the second color conversion portion 152 may be improved.

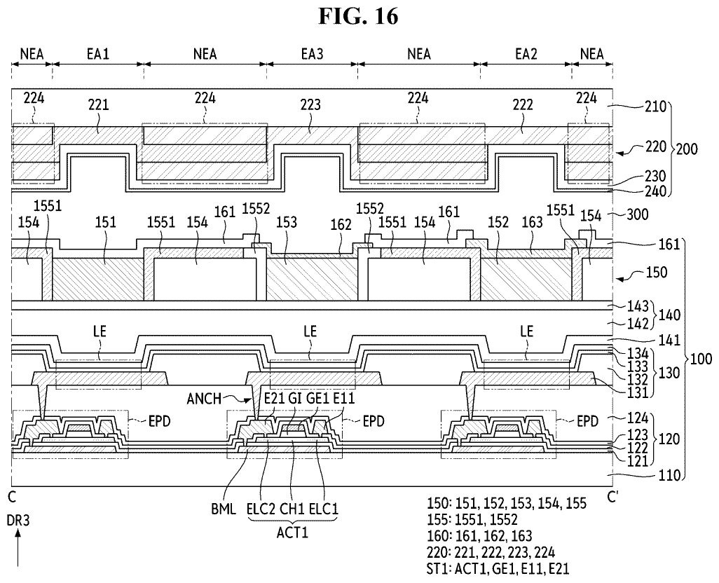

FIG. 16 is a cross-sectional view taken along line C-C′ of FIG. 3 according to an embodiment.

Since a display device 10 according to an embodiment illustrated in FIG. 16 is substantially the same as the display device 10 according to an embodiment illustrated in FIG. 14 and FIG. 15 a duplicate description thereof may be omitted below. In FIG. 16, the reflective wall 155 may include a second reflective wall portion 1552.

Since the second reflective wall portion 1552 according to an embodiment illustrated in FIG. 16 is the same as that of an embodiment illustrated in FIG. 9 and FIG. 10, a duplicate description thereof may be omitted below.

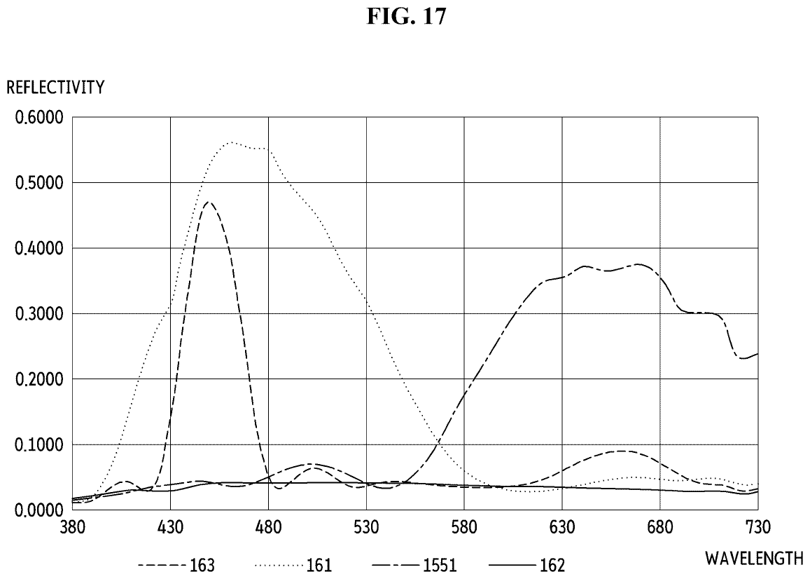

FIG. 17 is a simulation result graph illustrating reflectivity of each of a first reflective wall portion, a first color conversion capping portion, a second color conversion capping portion, and a third color conversion capping portion of FIG. 16.

As described above with reference to FIG. 7, the first reflective wall portion 1551 may include the first inorganic layers INL1 and the second inorganic layers INL2 that may be disposed with the first thickness TH1, and may be disposed alternately with each other.

As illustrated in FIG. 17, a reflectivity of the first reflective wall portion 1551 may be about 0.2 or more in a wavelength band of about 580 nm or more.

That is, light in the first wavelength band and light in the second wavelength band may be reflected by the first reflective wall portion 1551.

As a result, since the reflective wall 155 may reflect light even without including a reflective metal material, damage to the sealing layer 140 and the element layer 130 due to the process in a high temperature environment may be reduced.

As described herein with reference to FIG. 8, the first color conversion capping portion 161 may include the third inorganic layers INL3 and the fourth inorganic layers INL4 that may be disposed with the second thickness TH2 less than the first thickness TH1, and may be disposed alternately with each other.

As illustrated in FIG. 17, a reflectivity of the first color conversion capping portion 161 may be about 0.3 or more in a wavelength band of about 430 nm to about 530 nm.

That is, since the light in the second wavelength band or the light in the third wavelength band may be reflected by the first color conversion capping portion 161 and reused, a light emission efficiency of the first color conversion portion 151 and the second color conversion portion 152 may be improved.

As described above with reference to FIG. 12, the second color conversion capping portion 162 may include the seventh inorganic layers INL7 and the eighth inorganic layers INL8 that may be disposed with the fourth thickness TH4 less than the second thickness TH2, and may be disposed alternately with each other.

As illustrated in FIG. 17, a reflectivity of the second color conversion capping portion 162 may be less than about 0.1 throughout a wavelength band of visible light (about 380 nm to about 730 nm).

As a result, since light from the light transmitting portion 153 may be relatively efficiently emitted through the second color conversion capping portion 162 in the third light emitting area EA3, a light emission efficiency of the light transmitting portion 153 may be improved.

As described above with reference to FIG. 15, the third color conversion capping portion 163 may include the ninth inorganic layers INL9 and the tenth inorganic layers INL10. The ninth inorganic layers INL9 and the tenth inorganic layers INL10 may be disposed with the fifth thickness TH5 greater than the first thickness TH1 and disposed alternately with each other.

As illustrated in FIG. 17, a reflectivity of the third color conversion capping portion 163 may be about 0.1 or more in a wavelength band of about 430 nm to about 480 nm.

As a result, in the second light emitting area EA2, the light in the third wavelength band among the light of the second color conversion portion 152 may be reflected by the third color conversion capping portion 163, and the light in the second wavelength band may be relatively efficiently emitted through the third color conversion capping portion 163. Therefore, the light emission efficiency of the second color conversion portion 152 may be improved.

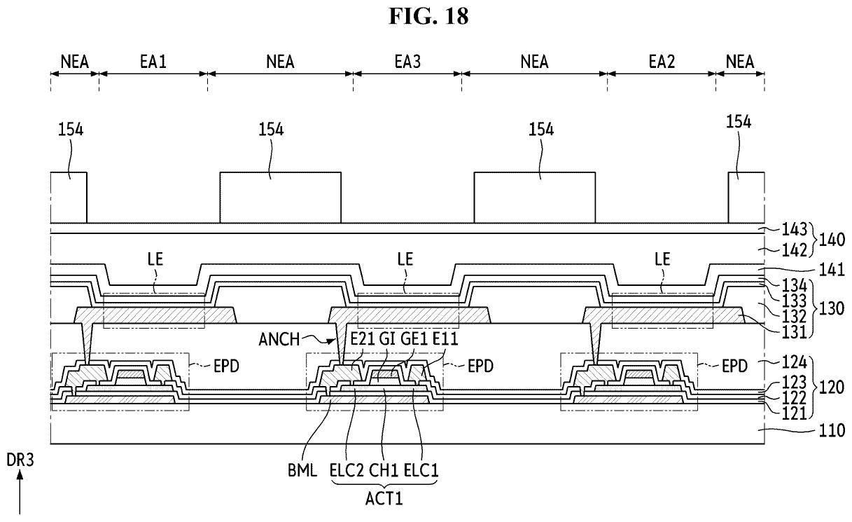

FIGS. 18, 19, 20, 21, 22, 23, 24, 25, and 26 are process views illustrating a process of disposing a color conversion layer and a process of disposing a color conversion capping layer according to an embodiment of FIG. 16.

According to some embodiments, a process of preparing a first substrate 100 may include a process of disposing a circuit layer 120, an element layer 130, and a sealing layer 140 on a first support substrate 110, and disposing a color conversion layer 150, and a process of disposing a color conversion capping layer 160.

Referring to FIG. 18, the process of disposing the color conversion layer 150 may include a process of disposing a partition wall 154 in a non-light emitting area NEA on the sealing layer 140.

In the process of disposing the partition wall 154, the partition wall 154 may be disposed by partially removing an organic material on the sealing layer 140.

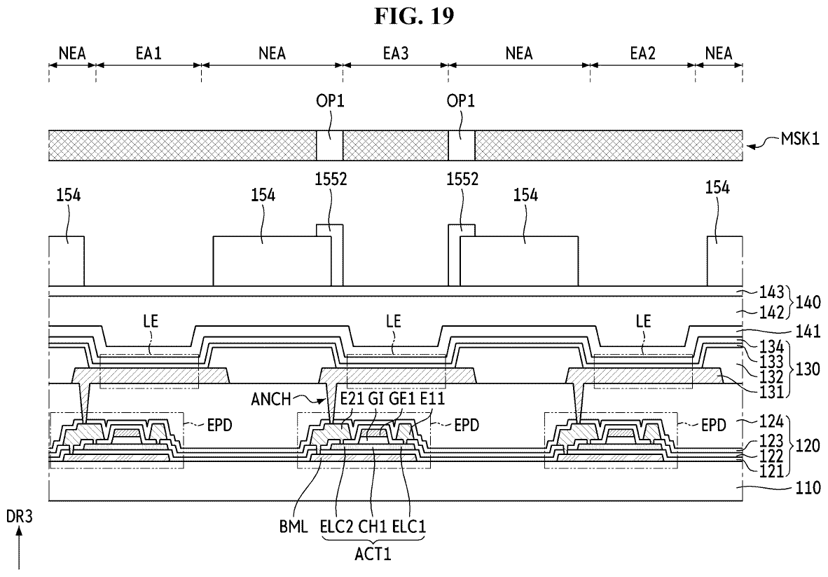

Referring to FIG. 19, the process of disposing the color conversion layer 150 may include a process of disposing a second reflective wall portion 1552 in a portion of the partition wall 154 that is in contact with a third light emitting area EA3 by alternately depositing different inorganic materials while equipped with a first mask MSK1 including a first opening OP1.

The first opening OP1 may face a portion of the non-light emitting area NEA surrounding the third emitting area EA3.

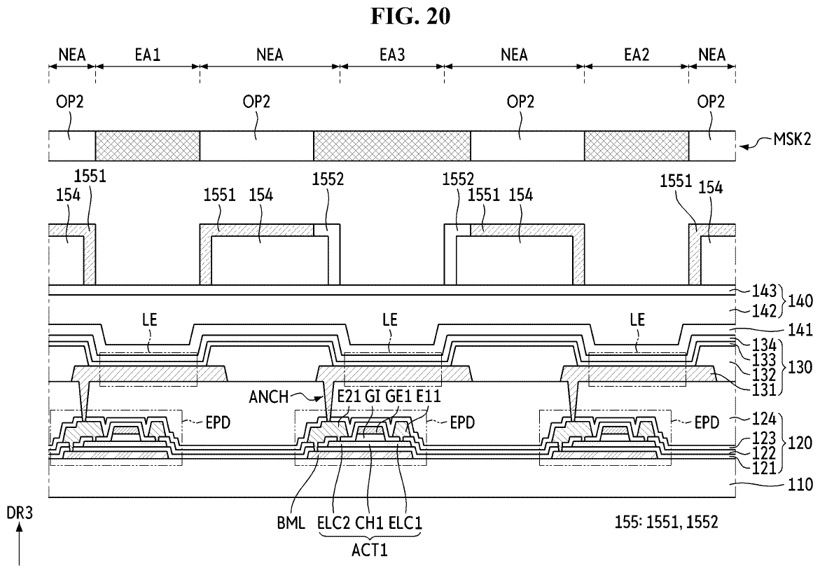

Referring to FIG. 20, the process of disposing the color conversion layer 150 may include a process of disposing a first reflective wall portion 1551 on the remaining portion of the partition wall 154 by alternately depositing different inorganic materials while equipped with a second mask MSK2 including a second opening OP2.

The second opening OP2 may face a portion of the non-light emitting area NEA except for a portion surrounding the third light emitting area EA3.

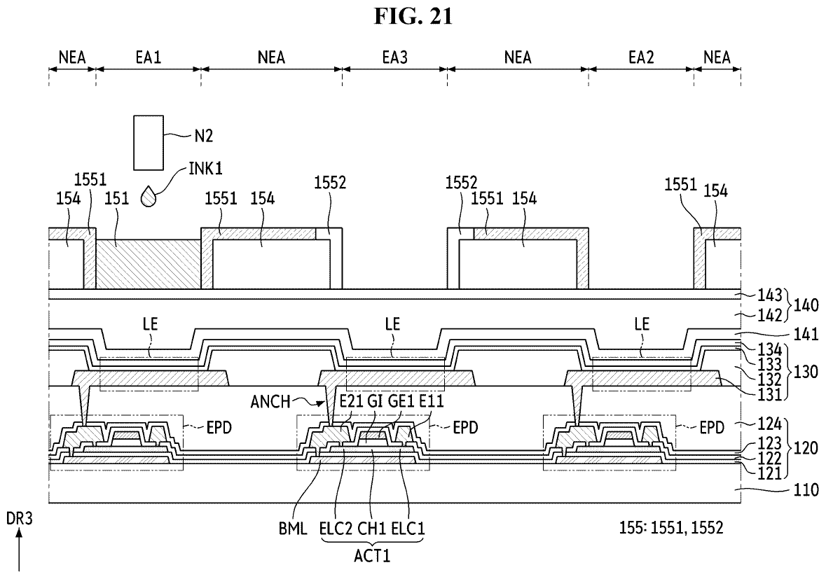

Referring to FIGS. 21, 22, and 23, the process of disposing the color conversion layer 150 may include a process of disposing a first color conversion portion 151, a process of disposing a second color conversion portion 152, and a process of disposing a light transmitting portion 153.

As illustrated in FIG. 21, the process of disposing the first color conversion portion 151 may include a process of discharging a first ink material INK1 within the first light emitting area EA1 surrounded by the partition wall 154 using a discharging device NZ that may move in a facing state on the display area DA.

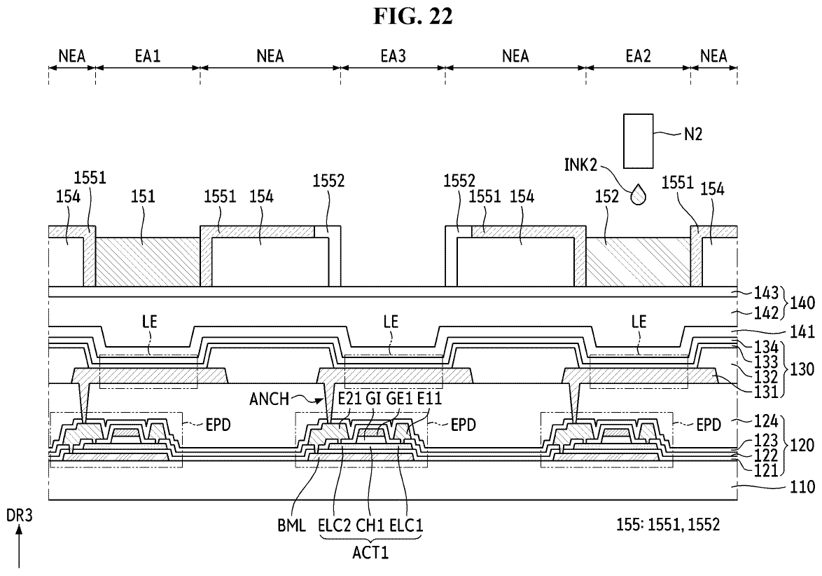

As illustrated in FIG. 22, the process of disposing the second color conversion portion 152 may include a process of discharging a second ink material INK2 within the second light emitting area EA2 surrounded by the partition wall 154 using a discharging device NZ that may move in a facing state on the display area DA.

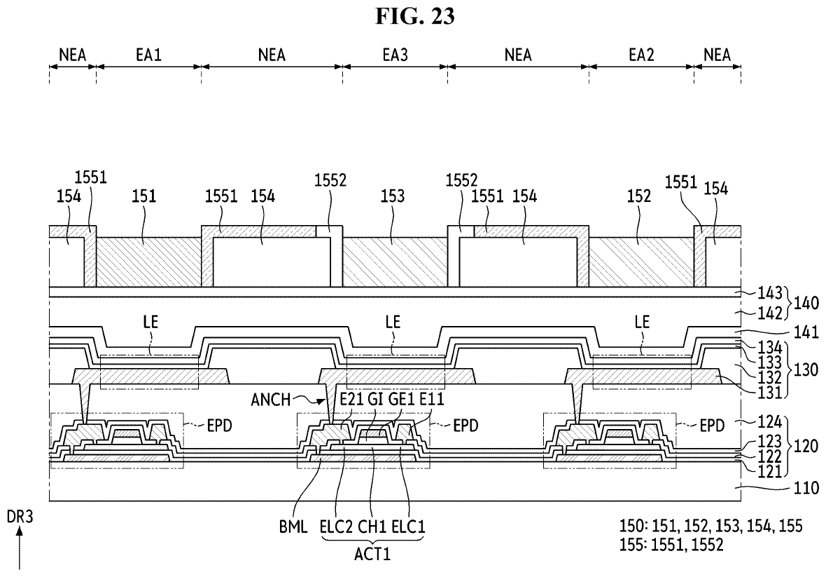

As illustrated in FIG. 23, the process of disposing the light transmitting portion 153 may include a process for selectively curing a light emitting material contained within the third light emitting area EA3 surrounded by the partition wall 154.

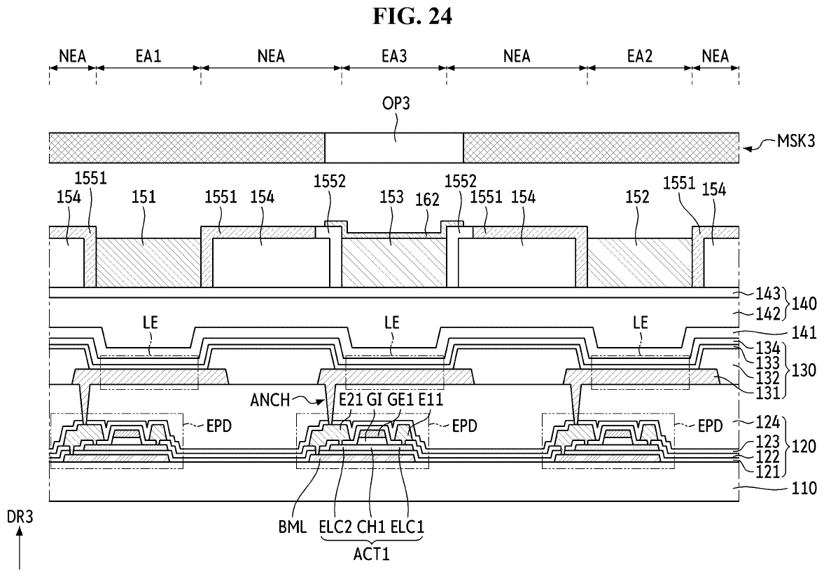

Referring to FIG. 24, the process of disposing the color conversion capping layer 160 may include a process of disposing a second color conversion capping portion 162 in the third light emitting area EA3 by alternately depositing different inorganic materials while equipped with a third mask MSK3 including a third opening OP3.

The third opening OP3 may face the third light emitting area EA3.

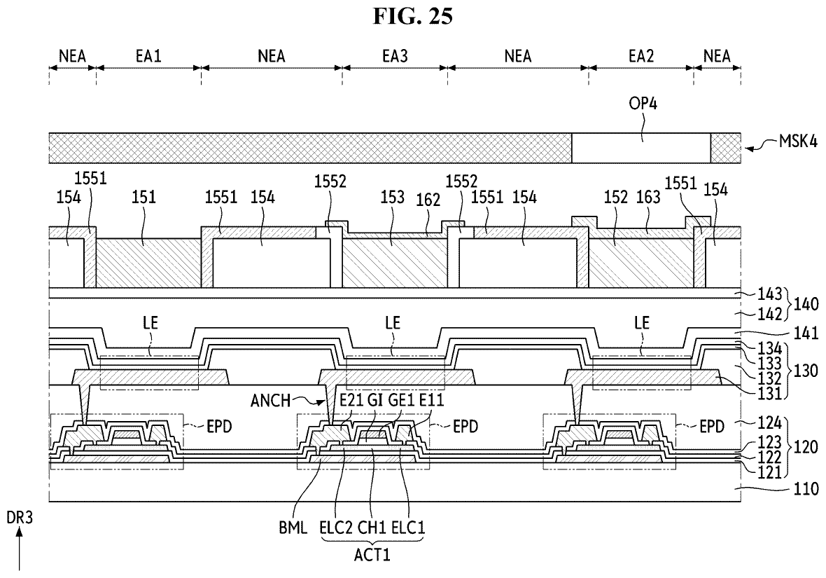

Referring to FIG. 25, the process of disposing the color conversion capping layer 160 may include a process of disposing a third color conversion capping portion 163 in the second light emitting area EA2 by alternately depositing different inorganic materials while equipped with a fourth mask MSK4 including a fourth opening OP4.

The fourth opening OP4 may face the second light emitting area EA2.

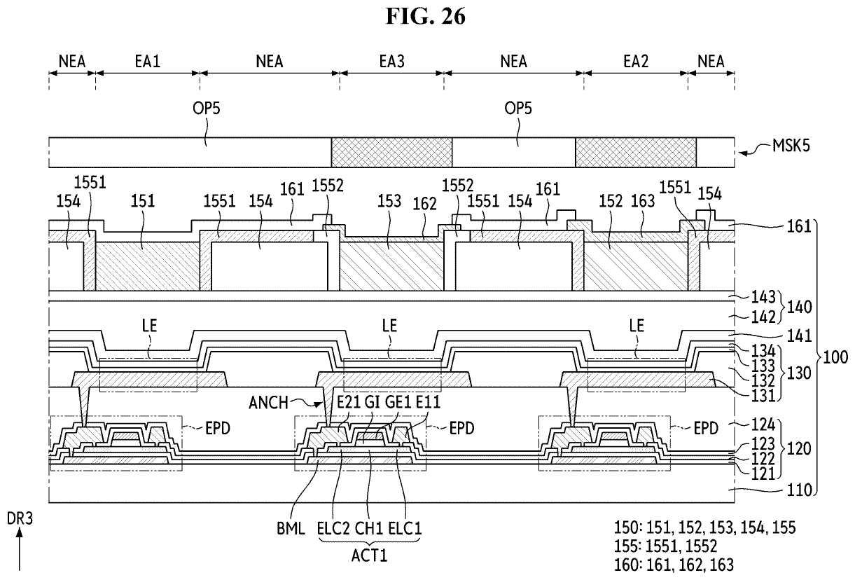

Referring to FIG. 26, the process of disposing the color conversion capping layer 160 may include a process of disposing a first color conversion capping portion 161 by alternately depositing different inorganic materials while equipped with a fifth mask MSK5 including a fifth opening OP5.

The fifth opening OP5 may face the remaining areas of the display area DA, and may be omitted from the second light emitting area EA2 and the third light emitting area EA3.

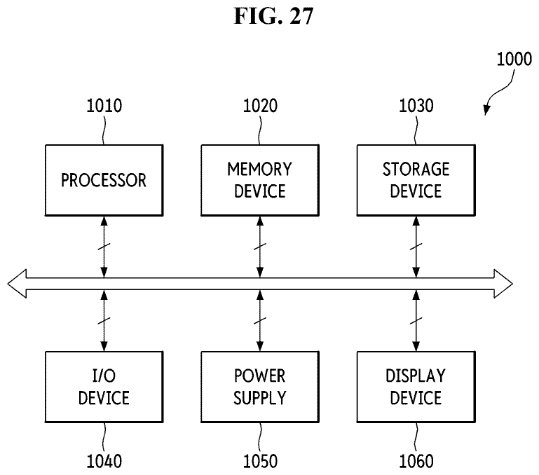

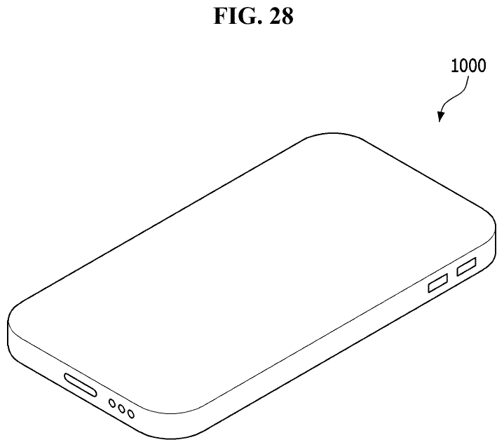

FIG. 27 is a block diagram illustrating an electronic device according to an embodiment of the present disclosure. FIG. 28 is a view illustrating an example in which the electronic device of FIG. 27 is implemented as a smart phone.

Referring to FIGS. 27 and 28, an electronic device 1000 may include a processor 1010, a memory device 1020, a storage device 1030, an input/output (I/O) device 1040, a power supply 1050, and a display device 1060. The display device 1060 may be the display device DD of FIG. 1. In addition, the electronic device 1000 may further include a plurality of ports for communicating with a video card, a sound card, a memory card, a universal serial bus (USB) device, other systems, and the like.

In an embodiment, as illustrated in FIG. 28, the electronic device 1000 may be implemented as a smart phone. However, the electronic device 1000 is not limited thereto. For example, the electronic device 1000 may be implemented as a smart pad, a smart watch, a tablet PC, a car navigation system, a computer monitor, a laptop, a head mounted display (“HMD”) device, and the like.

The processor 1010 may perform various computing functions. The processor 1010 may be a microprocessor, a central processing unit (“CPU”), an application processor (“AP”), and the like. The processor 1010 may be coupled to other components through an address bus, a control bus, a data bus, and the like. In an embodiment, the processor 1010 may be coupled to an extended bus such as a peripheral component interconnection (“PCI”) bus.

The memory device 1020 may store data for operations of the electronic device 1000. For example, the memory device 1020 may include at least one non-volatile memory device such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, a ferroelectric random access memory (“FRAM”) device, and the like and/or at least one volatile memory device such as a dynamic random access memory (“DRAM”) device, a static random access memory (“SRAM”) device, a mobile DRAM device, and the like.

The storage device 1030 may include a solid-state drive (“SSD”) device, a hard disk drive (“HDD”) device, a CD-ROM device, and the like. The I/O device 1040 may include an input device such as a keyboard, a keypad, a mouse device, a touch-pad, a touch-screen, and the like, and an output device such as a printer, a speaker, and the like. In some embodiments, the I/O device 1040 may include the display device 1060.

The power supply 1050 may provide power for operations of the electronic device 1000. In other words, the power supply 1050 may provide power to the display device 1060. The display device 1060 may be connected to other components through buses or other communication links.

Although embodiments of the present invention have been described with reference to the attached drawings, it will be understood by those of ordinary skill in the art that the present invention can be embodied in other specific forms without departing from the spirit or essential characteristics of the invention. Therefore, described embodiments are to be considered in all respects as illustrative and not restrictive.

What is claimed is:

1. A display device comprising:
a first support substrate including light emitting areas arranged in parallel and a non-light emitting area between the light emitting areas;
an element layer disposed on the first support substrate and including light emitting elements disposed in the light emitting areas;
a sealing layer disposed on the element layer; and
a color conversion layer disposed on the sealing layer,
the color conversion layer includes a partition wall disposed in the non-light emitting area, and a reflective wall covering a side surface of the partition wall,
the reflective wall includes a first reflective wall portion, and
the first reflective wall portion includes first inorganic layers having a first refractive index and second inorganic layers having a second refractive index and disposed alternately with the first inorganic layers, wherein the first refractive index and the second refractive index are different.

2. The display device of claim 1, wherein each of the first inorganic layers is disposed with a first thickness and each of the second inorganic layers is disposed with the first thickness.

3. The display device of claim 2, further comprising a color conversion capping layer covering the color conversion layer,
the color conversion capping layer includes a first color conversion capping portion disposed in at least one of the light emitting areas and the non-light emitting area,
the first color conversion capping portion includes third inorganic layers having a third refractive index and fourth inorganic layers having a fourth refractive index and disposed alternately with the third inorganic layers, wherein the third refractive index and the fourth refractive index are different, and
each of the third and fourth inorganic layers is disposed with a second thickness less than the first thickness.

4. The display device of claim 3, wherein the light emitting areas include:
a first light emitting area emitting light in a first wavelength band;
a second light emitting area emitting light in a second wavelength band lower than the first wavelength band; and
a third light emitting area emitting light in a third wavelength band lower than the second wavelength band,
the light emitting elements emit light in a fourth wavelength band which is equal to or lower than the third wavelength band,
the color conversion layer further includes:
a first color conversion portion disposed in the first light emitting area and converting the light in the fourth wavelength band into the light in the first wavelength band;
a second color conversion portion disposed in the second light emitting area and converting the light in the fourth wavelength band into the light in the second wavelength band; and
a light transmitting portion disposed in the third light emitting area and transmitting and scattering the light in the fourth wavelength band,
the partition wall is disposed between the first color conversion portion, the second color conversion portion, and the light transmitting portion, and
the first reflective wall portion is disposed between each of the first color conversion portion and the second color conversion portion and the partition wall.

5. The display device of claim 4, wherein the first thickness is about 95 nm to about 105 nm.

6. The display device of claim 4, wherein the first reflective wall portion is further disposed between the light transmitting portion and the partition wall.

7. The display device of claim 4, wherein the reflective wall further includes a second reflective wall portion disposed between the light transmitting portion and the partition wall,
the second reflective wall portion includes fifth inorganic layers having a fifth refractive index, and sixth inorganic layers having a sixth refractive index and disposed alternately with the fifth inorganic layers, wherein the fifth refractive index and the sixth refractive index are different, and
each of the fifth and sixth inorganic layers is disposed with a third thickness less than the first thickness.

8. The display device of claim 7, wherein the third thickness is about 65 nm to about 75 nm.

9. The display device of claim 4, wherein the first color conversion capping portion is disposed in the first light emitting area and the non-light emitting area, and
the second thickness is about 65 nm to about 75 nm.

10. The display device of claim 9, wherein the first color conversion capping portion is further disposed in the second light emitting area and the third light emitting area.

11. The display device of claim 4, wherein the color conversion capping layer further includes a second color conversion capping portion disposed in the third light emitting area,
the first color conversion capping portion is further disposed in the second light emitting area,
the second color conversion capping portion includes seventh inorganic layers having a seventh refractive index and eighth inorganic layers having an eighth refractive index and disposed alternately with the seventh inorganic layers, wherein the seventh refractive index and the eighth refractive index are different, and
each of the seventh and eighth inorganic layers is disposed with a fourth thickness less than the second thickness.

12. The display device of claim 11, wherein the fourth thickness is about 15 nm to about 25 nm.

13. The display device of claim 11, wherein the first color conversion capping portion covers an edge portion of the second color conversion capping portion.

14. The display device of claim 4, wherein the color conversion capping layer further includes:
a second color conversion capping portion disposed in the third light emitting area; and
a third color conversion capping portion disposed in the second light emitting area,
the second color conversion capping portion includes seventh inorganic layers having a seventh refractive index and eighth inorganic layers having an eighth refractive index and disposed alternately with the seventh inorganic layers, wherein the seventh refractive index and the eighth refractive index are different,
the third color conversion capping portion includes ninth inorganic layers having a ninth refractive index and tenth inorganic layers having a tenth refractive index and disposed alternately with the ninth inorganic layers, wherein the ninth refractive index and the tenth refractive index are different,
each of the seventh and eighth inorganic layers is disposed with a fourth thickness less than the second thickness, and
each of the ninth and tenth inorganic layers is disposed with a fifth thickness greater than the first thickness.

15. The display device of claim 14, wherein the fourth thickness is about 15 nm to about 25 nm, and
the fifth thickness is about 195 nm to about 205 nm, and
wherein the first color conversion capping portion covers an edge portion of each of the second color conversion capping portion and the third color conversion capping portion.

16. The display device of claim 4, further comprising:
a first substrate; and
a second substrate facing the first substrate,
wherein the first substrate includes the first support substrate, the element layer, the sealing layer, and the color conversion layer, and
wherein the second substrate includes:
a second support substrate facing the first substrate and including the light emitting areas and the non-light emitting area;
a color filter layer disposed on a surface of the second support substrate; and
a filter capping layer covering the color filter layer, and
the color filter layer includes:
a first filter portion disposed in the first light emitting area and transmitting the light in the first wavelength band;
a second filter portion disposed in the second light emitting area and transmitting the light in the second wavelength band;
a third filter portion disposed in the third light emitting area and transmitting the light in the third wavelength band; and
a light blocking portion defining the non-light emitting area.

17. The display device of claim 16, further comprising a filling layer filling a space between the first substrate and the second substrate,
wherein the filling layer is disposed between the color conversion capping layer and the filter capping layer.

18. The display device of claim 3, wherein an inorganic layer of the first inorganic layers is in contact with the color conversion layer,
the first refractive index of about 1.7 to about 2.0, and
the second refractive index of about 1.48 to about 1.6, and
wherein an inorganic layer of the third inorganic layers is in contact with the color conversion layer,
the third refractive index of about 1.48 to about 1.6, and
the fourth refractive index of about 1.7 to about 2.0.

19. A display device comprising:
a first support substrate including light emitting areas arranged in parallel and a non-light emitting area between the light emitting areas;
an element layer disposed on the first support substrate and including light emitting elements disposed in the light emitting areas;
a sealing layer disposed on the element layer;
a color conversion layer disposed on the sealing layer,
wherein the color conversion layer includes a partition wall disposed in the non-light emitting area, and a reflective wall covering a side surface of the partition wall,
the reflective wall includes a first reflective wall portion, and
the first reflective wall portion includes first inorganic layers having a first refractive index and second inorganic layers having a second refractive index and alternately disposed with the first inorganic layers, wherein the first refractive index and the second refractive index are different; and
a color conversion capping layer covering the color conversion layer and including a first color conversion capping portion disposed in at least one of the light emitting areas and the non-light emitting area,
wherein the first color conversion capping portion includes third inorganic layers having a third refractive index and fourth inorganic layers having a fourth refractive index and alternately disposed with the third inorganic layers, wherein the third refractive index and the fourth refractive index are different.

20. An electronic device including a display device comprising:
a first substrate; and
a second substrate facing the first substrate,
wherein the first substrate includes:
a first support substrate including light emitting areas arranged in parallel and a non-light emitting area between the light emitting areas;
an element layer disposed on the first support substrate and including light emitting elements disposed in the light emitting areas;
a sealing layer disposed on the element layer; and
a color conversion layer disposed on the sealing layer,
wherein the color conversion layer includes a partition wall disposed in the non-light emitting area, and a reflective wall covering a side surface of the partition wall,
the reflective wall includes a first reflective wall portion, and
the first reflective wall portion includes first inorganic layers having a first refractive index and second inorganic layers having a second refractive index and alternately disposed with the first inorganic layers, wherein the first refractive index and the second refractive index are different.
